(19) United States
(12) Patent Application Publication
(10) Pub. No.: US 2026/0173829 A1
(43) Pub. Date: Jun. 18, 2026

(54) SEMICONDUCTOR DEVICE MANUFACTURING METHOD AND SEMICONDUCTOR DEVICE MANUFACTURING APPARATUS

(71) Applicant: FUJI ELECTRIC CO., LTD., Kanagawa (JP)

(72) Inventors: Takeshi TAWARA, Tsukuba-city (JP); Tatsuhiko FUJIHIRA, Matsumoto-city (JP)

(21) Appl. No.: 19/369,296

(22) Filed: Oct. 26, 2025

(30) Foreign Application Priority Data
Dec. 12, 2024 (JP) 2024-218246
Apr. 4, 2025 (JP) 2025-062706

(51) Int. Cl. H10P 95/90; C23C 14/24; C23C 14/50; C23C 14/56

(52) U.S. Cl. CPC H10P 95/90; C23C 14/24; C23C 14/505; C23C 14/566

(57) ABSTRACT

Provided is a semiconductor device manufacturing method comprising: raising a temperature of a semiconductor substrate from a predetermined intake temperature to a predetermined deposition temperature; depositing, at a predetermined deposition position, a semiconductor layer on the semiconductor substrate at the deposition temperature; and lowering a temperature of the semiconductor substrate from the deposition temperature to a predetermined extraction temperature. The raising and the lowering may include at least one of: in the raising, moving the semiconductor substrate from an intake position to a temperature raising position different from the deposition position, or in the lowering, moving the semiconductor substrate from the deposition position to a temperature lowering position different from the deposition position.

The contents of the following patent application(s) are incorporated herein by reference:

NO. 2024-218246 filed in JP on December 12, 2024

NO. 2025-062706 filed in JP on April 4, 2025.

### BACKGROUND

### 1. TECHNICAL FIELD

The present invention relates to a semiconductor device manufacturing method and a semiconductor device manufacturing apparatus.

### 2. RELATED ART

A single wafer processing apparatus (for example, Patent documents 1 and 2) and a batch processing apparatus (for example, Patent document 3) are known as apparatuses for performing a deposition of a semiconductor layer on a semiconductor substrate.

### RELATED ART DOCUMENTS

### Patent document

Patent Document 1: Japanese Patent No. 5807505

Patent Document 2: Japanese Translation Publication of a PCT Route Patent Application No. 2023-540432

Patent Document 3: Japanese Patent No. 5560093

### BRIEF DESCRIPTION OF THE DRAWINGS

FIG. 1 is an example of a cross-section of a semiconductor device 300.

FIG. 2A is an example of a manufacturing method of the semiconductor device 300.

FIG. 2B is an example of a manufacturing method of the semiconductor device 300.

FIG. 3A is an example of a manufacturing apparatus 100 of the semiconductor device 300.

FIG. 3B is an example of temperature raising step S100 in the manufacturing apparatus 100.

FIG. 3C is an example of temperature lowering step S300 in the manufacturing apparatus 100.

FIG. 4 is an example of a manufacturing apparatus 500 of a comparative example.

FIG. 5 shows a comparison of the deposition time of a semiconductor layer.

FIG. 6 is a modified example of the manufacturing method of the semiconductor device 300.

FIG. 7A is an example of a manufacturing apparatus 200 of the semiconductor device 300.

FIG. 7B is an example of a heat exchanging portion 230.

FIG. 7C is an example of a heat exchange cycle in the manufacturing apparatus 200.

FIG. 8 is an example of a manufacturing apparatus 600 of a comparative example.

FIG. 9 shows a comparison of the deposition time of a semiconductor layer.

FIG. 10A is an example of a manufacturing apparatus 700 of the semiconductor device 300.

FIG. 10B is an example of a manufacturing apparatus 700 of the semiconductor device 300.

FIG. 11A is an example of a manufacturing apparatus 800 of the semiconductor device 300.

FIG. 11B is an example of a manufacturing apparatus 800 of the semiconductor device 300.

FIG. 12 is a modified example of the manufacturing apparatus 800 of the semiconductor device 300.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in implementation of a semiconductor device.

In the present specification, technical matters may be described by using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a -Z axis direction are directions opposite to each other. When a Z axis direction is described without describing the signs, it means that the direction is parallel to a +Z axis and a -Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

Each embodiment shows an example in which a first conductivity type is set as an N type, and a second conductivity type is set as a P type; however, the first conductivity type may be the P type, and the second conductivity type may be the N type. In this case, conductivity types of a substrate, a layer, a region, and the like in each embodiment respectively have opposite polarities.

In the present specification, a character N or P specifying a layer or a region means that electrons or holes are majority carriers, respectively. Also, ‘+’ and ‘-’ attached on ‘N’ and ‘P’ respectively mean that the higher doping concentration and the lower doping concentration than the layer or region to which it is not attached.

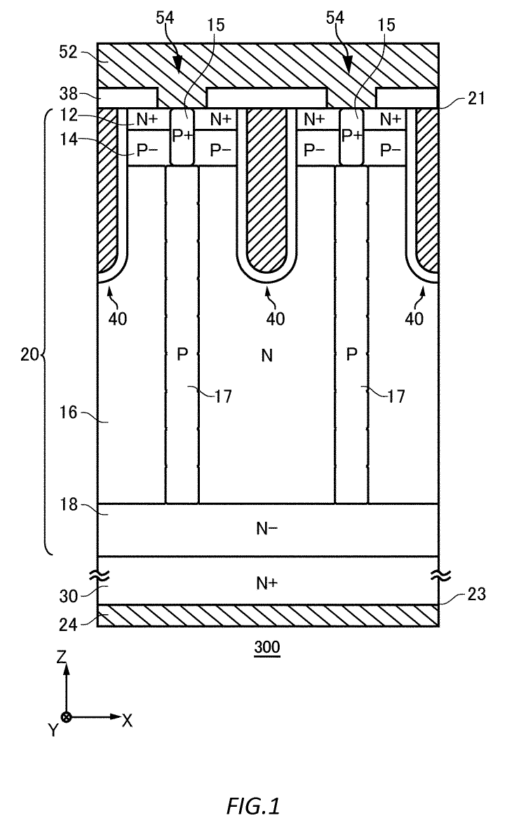

FIG. 1 shows an example of a cross-section of the semiconductor device 300. FIG. 1 is a cross-section orthogonal to a plurality of gate trench portions 40 provided to be arrayed in a predetermined array direction in the semiconductor device 300. The semiconductor device 300 of the present example comprises a substrate layer 30, a source region 12, a base region 14, a contact region 15, a semiconductor layer 20 in which a first conductivity-type region 16, a second conductivity type region 17 and a buffer region 18 are provided, an interlayer dielectric film 38, a gate trench portion 40, a front surface side electrode 52, and a back surface side electrode 24.

The substrate layer 30 is a substrate formed of a semiconductor material. The substrate layer 30 may be a silicon substrate, may be a silicon carbide substrate, or may be a semiconductor substrate of a compound such as gallium nitride. The substrate layer 30 of the present example is a silicon carbide substrate formed of silicon carbide of an N+ type.

The semiconductor layer 20 is a layer provided on the substrate layer 30, which is formed of a semiconductor material. The semiconductor layer 20 may be formed on the substrate layer 30 by epitaxial deposition. The semiconductor layer 20 may be formed of the same semiconductor material as that of the substrate layer 30 or may be formed of different semiconductor materials. The semiconductor layer 20 of the present example is a silicon carbide semiconductor layer provided on the substrate layer 30 that is formed of silicon carbide. The semiconductor layer 20 has a front surface 21.

The source region 12 is a region of a first conductivity type provided on the front surface 21 of the semiconductor layer 20. The source region 12 is of N+ type as an example. The source region 12 may be in contact with a side wall of the gate trench portions 40. The source region 12 of the present example is provided so as to extend from a side wall of one gate trench portion 40 to a side wall of another gate trench portion 40 adjacent thereto in an array direction of the gate trench portions 40.

The source region 12 may be formed by implanting a dopant of the first conductivity type from the front surface 21 of the semiconductor layer 20. As an example, a dopant for forming the source region 12 is phosphorus or nitrogen. A doping concentration of the source region 12 of the present example is higher than a doping concentration of the buffer region 18 described below. As an example, the doping concentration of the source region 12 is 1×10¹⁸cm⁻³ or more and 1×10²¹cm⁻³ or less.

The base region 14 is a region of a second conductivity type provided below the source region 12. The base region 14 is of the P- type as an example. The base region 14 may be provided on the front surface 21 of the semiconductor layer 20, in a region in which the source region 12 is not provided on the front surface 21 of the semiconductor layer 20.

The base region 14 may be formed by performing an epitaxial deposition of the semiconductor layer 20 above the buffer region 18 while doping a dopant of the second conductivity type. As an example, the dopant for forming the base region 14 is aluminum. A doping concentration of the base region 14 of the present example is higher than a doping concentration of the buffer region 18. As an example, the doping concentration of the base region 14 is 2×10¹⁶cm⁻³ or more and 2×10¹⁷cm⁻³ or less.

The contact region 15 is a region of a second conductivity type that is provided above the buffer region 18 and that has a doping concentration higher than that of the base region 14. The contact region 15 is of P+ type as an example. The contact region 15 is provided to extend from the semiconductor layer 20 in a depth direction of the semiconductor layer 20. The contact region 15 is provided to be spaced apart from the gate trench portion 40.

The contact region 15 may be formed by implanting a dopant of the second conductivity type from the front surface 21 of the semiconductor layer 20. As an example, a dopant for forming the contact region 15 is aluminum or boron. A doping concentration of the contact region 15 may be higher than the doping concentration of the base region 14. As an example, the doping concentration of the contact region 15 is 1×10¹⁹cm⁻³ or more and 1×10²⁰cm⁻³ or less.

The first conductivity-type region 16 is a region of the first conductivity type provided above the buffer region 18. The first conductivity-type region 16 is of N type as an example. The first conductivity-type region 16 of the present example is provided from a lower end of the base region 14 to an upper end of the buffer region 18 in a depth direction of the semiconductor layer 20.

The first conductivity-type region 16 may be formed by performing an epitaxial deposition of the semiconductor layer 20 above the buffer region 18 while doping a dopant of the first conductivity type. As an example, the dopant for forming the first conductivity-type region 16 is nitrogen. A doping concentration of the first conductivity-type region 16 may be higher than the doping concentration of the buffer region 18. As an example, the doping concentration of the first conductivity-type region 16 is 1×10¹⁶cm⁻³ or more and 1×10¹⁷cm⁻³ or less.

The second conductivity type region 17 is a region of the second conductivity type provided above the buffer region 18. The second conductivity type region 17 is of P type as an example. The second conductivity type region 17 is provided from a lower end of the contact region 15 to an upper end of the buffer region 18 in the depth direction of the semiconductor layer 20.

The second conductivity type region 17 may be formed by implanting a dopant of the second conductivity type from above the first conductivity-type region 16. As an example, a dopant for forming the second conductivity type region 17 is aluminum. A doping concentration of the second conductivity type region 17 may be higher than the doping concentration of the base region 14, or may be lower than the doping concentration of the contact region 15. As an example, the doping concentration of the second conductivity type region 17 is 1×10¹⁶cm⁻³ or more and 1×10¹⁷cm⁻³ or less.

The first conductivity-type region 16 and the second conductivity type region 17 may be formed alternately. As an example, the second conductivity type region 17 is formed by implanting the dopant of the second conductivity type from above the first conductivity-type region 16 after forming the first conductivity-type region 16 by performing the epitaxial deposition of the semiconductor layer 20 while doping the dopant of the first conductivity type. The first conductivity-type region 16 and the second conductivity type region 17 may be formed by performing the epitaxial deposition and implanting the dopant alternately and repeatedly.

The buffer region 18 is a region of the first conductivity type provided on the substrate layer 30. The buffer region 18 is of N- type as an example. The buffer region 18 may be formed by performing an epitaxial deposition of the semiconductor layer 20 while doping a dopant of the first conductivity type. The buffer region 18 of the present example is formed, on the substrate layer 30 of silicon carbide, by performing an epitaxial deposition of silicon carbide while doping nitrogen.

The buffer region 18 may be a region in which a semiconductor layer 20 without the dopant introduced thereto remains. That is, the doping concentration of the buffer region 18 may be a doping concentration of the semiconductor layer 20.

The gate trench portion 40 is provided on the front surface 21 of the semiconductor layer 20. The gate trench portion 40 may be provided to penetrate the base region 14 to reach the first conductivity-type region 16. A configuration in which the gate trench portion 40 penetrates the base region 14 is not limited to a configuration which is fabricated by forming the base region 14 and then forming the gate trench portion 40. A configuration in which the base region 14 is formed on the side wall of the gate trench portion 40 after the gate trench portion 40 is formed is also included in the configuration in which the gate trench portion 40 penetrates the base region 14.

The front surface side electrode 52 is set to a source potential and provided above the substrate layer 30 with the interlayer dielectric film 38 sandwiched therebetween. The front surface side electrode 52 is formed of a material including metal. The front surface side electrode 52 may include a barrier metal. At least a partial region of the front surface side electrode 52 may be formed of metal such as aluminum (Al) or metal alloy such as aluminum-silicon alloy (AlSi), aluminum-silicon-copper alloy (AlSiCu).

The back surface side electrode 24 is formed on a back surface 23 of the substrate layer 30. The back surface side electrode 24 is formed of a conductive material such as metal. For example, a single-layer film formed of gold (Au), or a metal film formed by stacking in a sequence of titanium (Ti), nickel (Ni) and Au is usable as the back surface side electrode 24, and a metal film of molybdenum (Mo), tungsten (W) or the like may further e stacked on its lowermost layer. Also, a silicide layer formed of nickel silicide (NiSix) or the like may be provided between the back surface 23 of the substrate layer 30 and the back surface side electrode 24.

The interlayer dielectric film 38 is provided above the front surface 21. A front surface side electrode 52 is provided above the interlayer dielectric film 38. On the interlayer dielectric film 38, one or more contact holes 54 for electrically connecting the front surface side electrode 52 and the substrate layer 30 are provided.

The contact hole 54 is formed above each region of the source region 12 and the contact region 15. The contact hole 54 may be provided to extend in a trench extending direction of the gate trench portion 40. Inside the contact hole 54, a plug formed of tungsten or the like may be formed. Inside the contact hole 54, the front surface side electrode 52 and the semiconductor layer 20 are electrically connected.

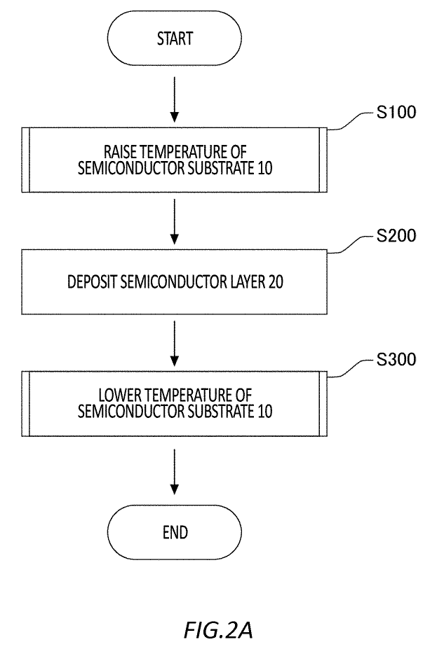

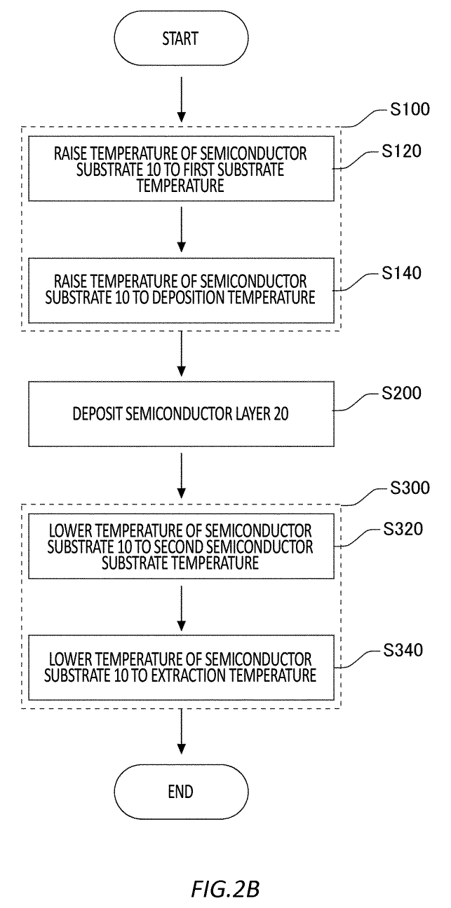

FIG. 2A is an example of a manufacturing method of the semiconductor device 300. The manufacturing method of the present example comprises step S100 that performs a temperature raising of the semiconductor substrate 10, step S200 that performs a deposition of the semiconductor layer 20, and step S300 that performs a temperature lowering of the semiconductor substrate 10.

In step S100, the temperature of the semiconductor substrate 10 is raised from a predetermined intake temperature to a predetermined deposition temperature. The intake temperature is the temperature in an intake position to which the semiconductor substrate 10 is taken in, in a deposition apparatus in which the semiconductor layer 20 is deposited on the semiconductor substrate 10. The intake temperature is higher than the room temperature and lower than the deposition temperature. The intake temperature may be 300℃ or more, or may be 1200℃ or less. The intake temperature may be 600℃ or more, or may be 900℃ or less. In an example, the intake temperature is 600℃.

The deposition temperature may be a temperature at which the density of the crystal defect in the deposited semiconductor layer 20 that causes a characteristic failure of the semiconductor device 300 is one per cm⁻³ or less. When the semiconductor layer 20 is a silicon carbide semiconductor, the deposition temperature may be 1500℃ or more, or may be 1700℃ or less. In an example, the deposition temperature is 1600℃.

In step S200, the semiconductor layer 20 is deposited on the semiconductor substrate 10. Step S200 is performed at a temperature that is equal to or greater than the deposition temperature in a situation in which the semiconductor substrate 10 is positioned at a predetermined deposition position. The semiconductor layer 20 may be deposited by using Chemical Vapor Deposition (CVD) or may be deposited by using close-spaced sublimation method. In step S200, in a condition in which the temperature of the semiconductor substrate 10 is equal to or greater than the deposition temperature, the semiconductor layer 20 may be epitaxially deposited on the semiconductor substrate 10 by introducing a gaseous mixture obtained by mixing carrier gas and raw material gas. The raw material gas may be a gas including silicon, may be a gas including carbon, or may be a gas including nitrogen. In an example, the semiconductor layer 20 of silicon carbide is deposited by introducing, for the semiconductor substrate 10 of silicon carbide that is heated to a temperature equal to or greater than the deposition temperature, a gaseous mixture of monosilane and propane using hydrogen as a carrier gas.

In step S300, the temperature of the semiconductor substrate 10 is lowered to a predetermined extraction temperature from the deposition temperature. The extraction temperature is a temperature equal to or less than the heatproof temperature of the arm for extraction for extracting the semiconductor substrate 10 after depositing the semiconductor layer 20. The extraction temperature may be 600℃ or more, or may be 1200℃ or less. The extraction temperature may be 600℃ or more, or may be 900℃ or less. In an example, the extraction temperature is 600℃. The extraction temperature may be the same as or may be different from the intake temperature.

FIG. 2B is an example of a manufacturing method of the semiconductor device 300. In step S100, step S120 that raises the temperature of the semiconductor substrate 10 to a first substrate temperature, and step S140 that raises the temperature of the semiconductor substrate 10 to the deposition temperature may be included. In step S300, step S320 that lowers the temperature of the semiconductor substrate 10 to a second substrate temperature, and step S340 that lowers the temperature of the semiconductor substrate 10 to an extraction temperature may be included. Description for step S200 that deposits the semiconductor layer 20 is omitted since it is similar to FIG. 2A.

In step S120, the temperature of the semiconductor substrate 10 is raised to the first substrate temperature. The first substrate temperature is higher than the intake temperature and lower than the deposition temperature. The first substrate temperature may be 600℃ or more, or may be 1200℃ or less. As an example, the first substrate temperature is 900℃. In step S120, the temperature of the semiconductor substrate 10 may be raised from the intake temperature to the first substrate temperature by moving the semiconductor substrate 10 from the intake position to a temperature raising position that is different from the deposition position.

After step S120, in step S140, the temperature of the semiconductor substrate 10 is raised from the first substrate temperature to the deposition temperature. In step S140, the temperature of semiconductor substrate 10 may be raised from the first substrate temperature to the deposition temperature by moving the semiconductor substrate 10 from the temperature raising position to the deposition position.

In step S320, the temperature of the semiconductor substrate 10 is lowered to the second substrate temperature. The second substrate temperature is higher than the extraction temperature and lower than the deposition temperature. The second substrate temperature may be 600℃ or more, or may be 1200℃ or less. The second substrate temperature may be the same as or may be different from the first substrate temperature. In step S320, the temperature of the semiconductor substrate 10 may be lowered from the deposition temperature to the second substrate temperature by moving the semiconductor substrate 10 from the deposition position to a temperature lowering position different from the deposition position.

After step S320, in step S340, the temperature of the semiconductor substrate 10 is lowered from the second substrate temperature to the extraction temperature. In step S340, the temperature of the semiconductor substrate 10 may be lowered from the second substrate temperature to the extraction temperature by moving the semiconductor substrate 10 from the temperature lowering position to the extraction position.

The manufacturing method of the semiconductor device 300 of the present example includes at least one of step S120 or step S320. Specific examples of step S100 and step S300 are described below in conjunction with a description of the operation of a manufacturing apparatus of the semiconductor device 300.

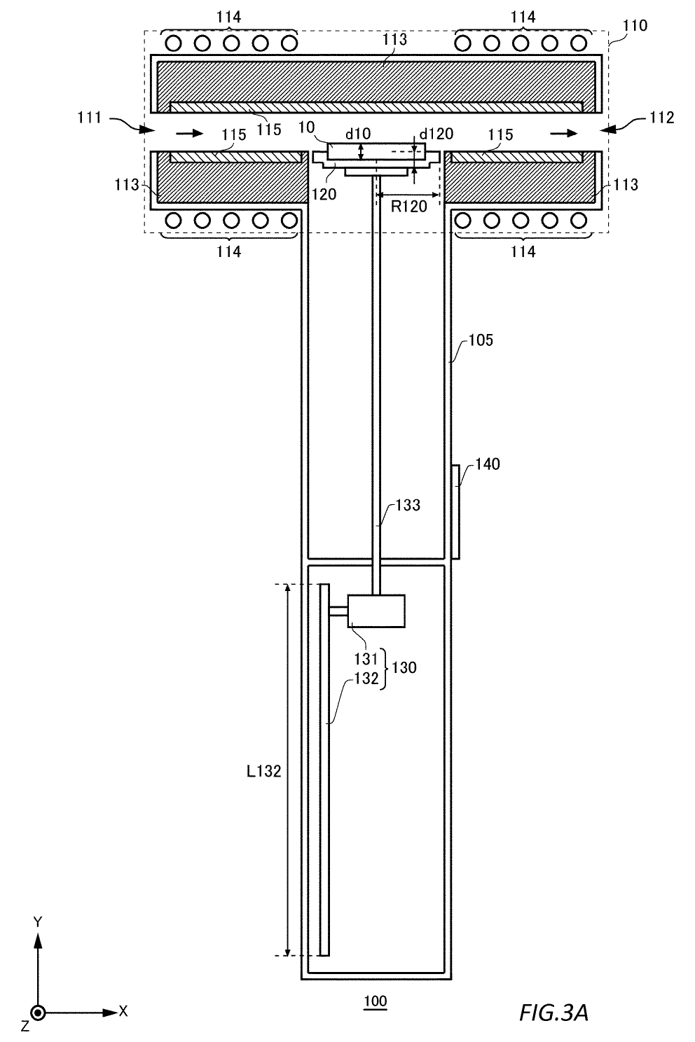

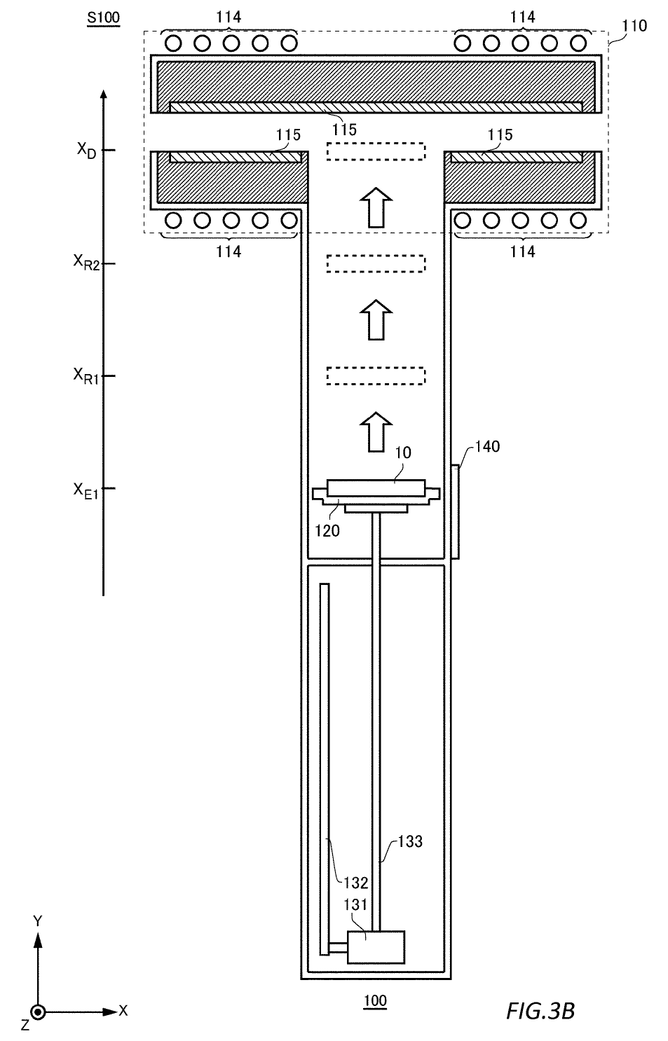

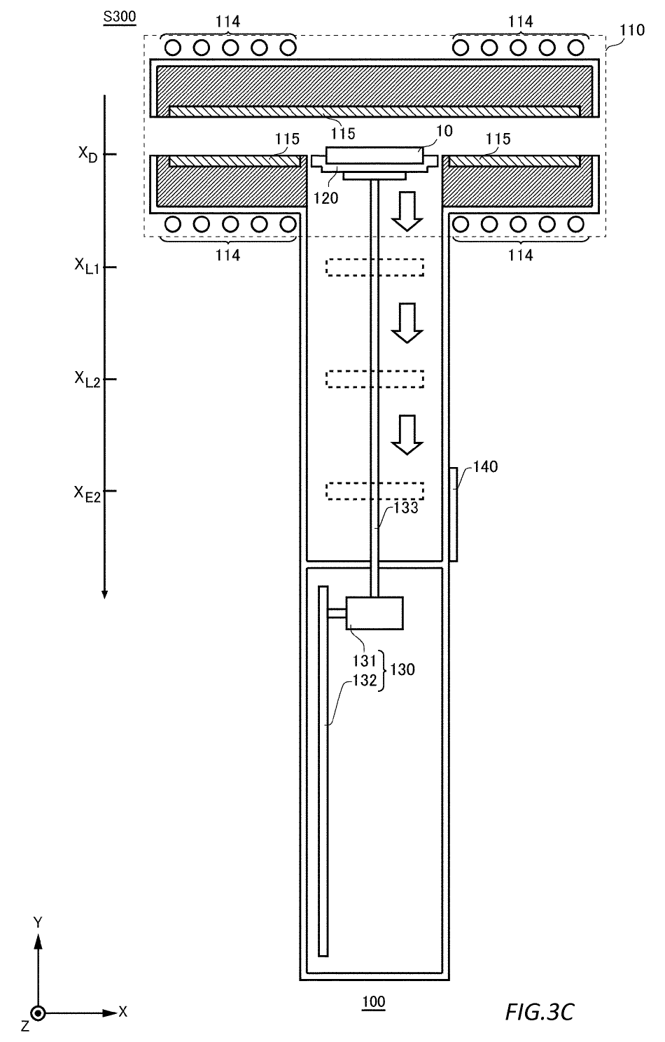

FIG. 3A shows a cross-sectional view of a manufacturing apparatus 100 of the semiconductor device 300. An outer wall 105 of the manufacturing apparatus 100 is composed of a transparent quartz, an opaque quartz, or the like that is highly heat-resistant. The manufacturing apparatus 100 of the present example comprises a deposition chamber 110, a susceptor 120, a distance adjusting portion 130, and a gate valve 140. The deposition chamber 110 has a gas introduction tube 111, a gas discharge pipe 112, a thermal insulation material 113, an inductive heating coil 114, and a heating element 115.

The deposition chamber 110 deposits a semiconductor layer 20 on the semiconductor substrate 10 that is positioned at a predetermined deposition position. An interior of the deposition chamber 110 is heated by the heating element 115 that raises the temperature of the semiconductor substrate 10 to a predetermined deposition temperature. In the deposition chamber 110, the semiconductor layer 20 can be deposited on the semiconductor substrate 10 by introducing a carrier gas and a raw material gas from the gas introduction tube 111 after raising the temperature of the semiconductor substrate 10 to the deposition temperature. The carrier gas and the raw material gas are discharged to the outside of the deposition chamber 110 from the gas discharge pipe 112.

The heating element 115 is heated by an electromagnetic induction. The heating element 115 may be heated by the inductive heating coil 114 provided along the outer circumference of the deposition chamber 110. Since one of ordinary skill in the art can understand a specific configuration of the heating element 115 that is heated by the electromagnetic induction, the description will be omitted.

Inside the deposition chamber 110, the heating element 115 is covered by the thermal insulation material 113. Thereby, the interior of the deposition chamber 110 can be efficiently heated without leaking heat generated by the heating element 115 to the outside.

The susceptor 120 is mounted with the semiconductor substrate 10. The susceptor 120 is provided to have a circular shape in a top view. The susceptor 120 may be composed of the same material as that of the semiconductor substrate 10. Thereby, a specific heat of the susceptor 120 can be the same as a specific heat of the semiconductor substrate 10, and the temperature of each of the semiconductor substrate 10 and the susceptor 120 can be uniform. Note that even if the susceptor 120 is composed of a different material from the material of the semiconductor substrate 10, as long as the susceptor 120 is composed of a material having the specific heat similar to the specific heat of the semiconductor substrate 10, a similar effect can be obtained.

The distance adjusting portion 130 changes the distance between the semiconductor substrate 10 and the heating element 115. The distance adjusting portion 130 may include, in a top view, a rotary element 131 that rotates the semiconductor substrate 10 and a distance change element 132 for changing the distance between the semiconductor substrate 10 and the heating element 115. The distance adjusting portion 130 may include a rod element 133 provided between the rotary element 131 and the susceptor 120. The distance adjusting portion 130 of the present example changes the distance between the semiconductor substrate 10 and the heating element 115 by moving the susceptor 120 and the semiconductor substrate 10 in a vertical direction (in FIG. 3A, the Y axis direction) between the intake position or the extraction position and the deposition position.

When the heating element 115 is heated to a predetermined temperature, the temperature inside the manufacturing apparatus 100 is high at the position near the heating element 115, and a temperature gradient is generated, which makes the temperature decrease as the distance from the heating element 115 increases. In the example of FIG. 3A, the temperature inside the deposition chamber 110 is the highest, and the temperature near the gate valve 140 is the lowest. If the temperature inside the deposition chamber 110 is set as the deposition temperature, and the temperature near the gate valve 140 is set as the intake temperature or the extraction temperature, the distance adjusting portion 130 can change the distance between the semiconductor substrate 10 and the heating element 115 in a state in which the temperature of the semiconductor substrate 10 is higher than the intake temperature or the extraction temperature, and lower than the deposition temperature.

Because the semiconductor substrate 10 and the susceptor 120 are sufficiently thin, and has a high thermal conductivity, it can be approximated that the semiconductor substrate 10 and the susceptor 120 have the same temperature as the ambient temperature where the semiconductor substrate 10 and the susceptor 120 are positioned. In an example, a thickness d10 of the semiconductor substrate 10 is 350 µm or more and 500 µm or less, and a thickness d120 of the susceptor 120 is 350 µm or more and 500 µm or less.

The thickness of each of the semiconductor substrate 10 and the susceptor 120 may be substantially the same. In an example, the thickness d120 of the susceptor 120 is 70% or more and 100% or less of the thickness d10 of the semiconductor substrate 10. Thereby, the temperature of each of the semiconductor substrate 10 and the susceptor 120 can be substantially the same.

The change in the distance according to the distance adjusting portion 130 may occur at around a speed at which the substrate temperature of the semiconductor substrate 10 is sufficiently heated to be the same as the ambient temperature of the semiconductor substrate 10. The distance adjusting portion 130 may change the distance between the semiconductor substrate 10 and the heating element 115 at a constant speed. The speed at which the distance adjusting portion 130 changes the distance between the semiconductor substrate 10 and the heating element 115 may be 50cm/min or more or may be 100cm/min or less.

The rotary element 131 can rotate the semiconductor substrate 10 in an XZ plane. Thereby, the temperature irregularity generated on the semiconductor substrate 10 can be reduced, and the semiconductor layer 20 can be uniformly deposited.

The distance change element 132 is provided inside the manufacturing apparatus 100. In the manufacturing apparatus 100 of the present example, the distance between the semiconductor substrate 10 and the heating element 115 is changed by moving the rotary element 131 up and down along the distance change element 132. The distance change element 132 can be composed of a material that is not highly heat-resistant, since it is not affected by the heat of the heating element 115.

The length L132 of the distance change element 132 is equal to or greater than the length with which the substrate temperature of the semiconductor substrate 10 can be lowered to be equal to or less than the extraction temperature. In an example, the length L132 of the distance change element 132 is five times or more and ten times or less the radius R120 of the susceptor 120.

The rod element 133 is composed of a material having a heat capacity similar to that of the semiconductor substrate 10 and the susceptor 120. Thereby, the temperature of the semiconductor substrate 10 can be efficiently raised and lowered. In an example, when the semiconductor substrate 10 is a silicon carbide semiconductor substrate, the rod element 133 is also composed of a silicon carbide material.

The gate valve 140 is provided on the outer wall 105 of the manufacturing apparatus 100. In the present example, one gate valve 140 is provided at the extraction position of the manufacturing apparatus 100, but it is not limited thereto. The gate valve 140 may be provided at each of the intake position and the extraction position.

The manufacturing apparatus 100 can place, via the gate valve 140, the susceptor 120 in which the semiconductor substrate 10 is mounted inside the manufacturing apparatus 100, to extract the semiconductor substrate 10 with the semiconductor layer 20 deposited thereon. A plurality of gate valves 140 that are three or more may be provided. Thereby, for semiconductor materials with different deposition temperatures, intake temperatures and extraction temperatures, the semiconductor layer 20 can be deposited on the semiconductor substrate 10 using one apparatus.

FIG. 3B shows an example of a temperature raising step S100 in the manufacturing apparatus 100. With reference to FIG. 3B, the change in the distance between the semiconductor substrate 10 and the heating element 115 in the temperature raising step S100 is described.

In step S100, the distance adjusting portion 130 moves the semiconductor substrate 10, from an intake position X_{E1}, to a temperature raising position that is closer to the heating element 115 than the intake position X_{E1} and that is further spaced apart from the heating element 115 than the deposition position X_{D}. Thereby, the temperature of the semiconductor substrate 10 is raised to the first substrate temperature that is higher than the intake temperature and lower than the deposition temperature.

In the example of FIG. 3B, the temperature raising position includes a low temperature side temperature raising position X_{R1}, and a high temperature side temperature raising position X_{R2}. These positions are arbitrary two points between the intake position X_{E1} and the deposition position X_{D}, and the positions are not particularly limited.

The low temperature side temperature raising position X_{R1} is a position that is further spaced apart from the heating element 115 than the high temperature side temperature raising position X_{R2}. The distance between the low temperature side temperature raising position X_{R1} and the heating element 115 is greater than the distance between the high temperature side temperature raising position X_{R2} and the heating element 115. That is, the low temperature side temperature raising position X_{R1} has a temperature lower than the high temperature side temperature raising position X_{R2}.

The high temperature side temperature raising position X_{R2} is closer to the heating element 115 than the low temperature side temperature raising position X_{R1}, and further spaced apart from the heating element 115 than the deposition position X_{D}. The distance between the high temperature side temperature raising position X_{R2} and the heating element 115 is greater than the distance between the deposition position X_{D} and the heating element 115. That is, the high temperature side temperature raising position X_{R2} has a temperature lower than that of the deposition position X_{D}.

Step S100 includes a step for moving the semiconductor substrate 10 from the low temperature side temperature raising position X_{R1}to the high temperature side temperature raising position X_{R2}, with a temperature higher than that of the low temperature side temperature raising position X_{R1}. Step S100 may include a step for moving the semiconductor substrate 10 from the intake position X_{E1} to the low temperature side temperature raising position X_{R1}, with a temperature higher than that of the intake position X_{E1}. The step S100 may include a step for moving the semiconductor substrate 10 from the high temperature side temperature raising position X_{R2} to the deposition position X_{D}, with a temperature higher than that of the high temperature side temperature raising position X_{R2}.

In step S100, the semiconductor substrate 10 may be moved in the order of the intake position X_{E1}, the low temperature side temperature raising position X_{R1}, the high temperature side temperature raising position X_{R2}, and the deposition position X_{D}. Thereby, the temperature of the semiconductor substrate 10 can be gradually raised.

The temperature raising step S100 includes raising the temperature of the semiconductor substrate 10 by bringing the semiconductor substrate 10 close to the heating element 115 that is heated to a predetermined temperature. The temperature of the heating element 115 may be constant at the deposition temperature. In the temperature raising step S100 of the present example, even if the temperature of the heating element 115 is constant, by changing the distance between the heating element 115 and the semiconductor substrate 10, the temperature of the semiconductor substrate 10 can be changed. Thereby, since the time for heating the heating element 115 is not required, the temperature of the semiconductor substrate 10 can be raised more quickly than in the case in which the temperature of the heating element 115 is changed.

FIG. 3C shows an example of temperature lowering step S300 in the manufacturing apparatus 100. With reference to FIG. 3C, the change in the distance between the semiconductor substrate 10 and the heating element 115 in the temperature lowering step S300 is described.

In step S300, the distance adjusting portion 130 moves the semiconductor substrate 10 from the deposition position X_{D} to the temperature lowering position that is further spaced apart from the heating element 115 than the deposition position X_{D}. Thereby, the temperature of the semiconductor substrate 10 is lowered to the second substrate temperature that is higher than the extraction temperature and lower than the deposition temperature.

In the example of FIG. 3C, the temperature lowering position includes the high temperature side temperature lowering position X_{L1} and the low temperature side temperature lowering position X_{L2}. These positions are arbitrary two points between the deposition position X_{D} and the extraction position X_{E2}, and the positions are not particularly limited.

The high temperature side temperature lowering position X_{L1} is a position that is closer to the heating element 115 than the low temperature side temperature lowering position X_{L2}, and further spaced apart from the heating element 115 than the deposition position X_{D}. The distance between the high temperature side temperature lowering position X_{L1} and the heating element 115 is smaller than the distance between the low temperature side temperature lowering position X_{L2} and the heating element 115. That is, the high temperature side temperature lowering position X_{L1} has a temperature higher than the low temperature side temperature lowering position X_{L2}.

The distance between the high temperature side temperature lowering position X_{L1} and the heating element 115 is greater than the distance between the deposition position X_{D} and the heating element 115. That is, the high temperature side temperature lowering position X_{L1} has a temperature lower than that of the deposition position X_{D}. By moving the semiconductor substrate 10 to the high temperature side temperature lowering position X_{L1} that has a temperature lower than that of the deposition position X_{D}, the temperature of the semiconductor substrate 10 can be lowered to a temperature lower than that of the deposition temperature.

The low temperature side temperature lowering position X_{L2} is further spaced apart from the heating element 115 than the high temperature side temperature lowering position X_{L1}. The distance between the low temperature side temperature lowering position X_{L2} and the heating element 115 is greater than the distance between the high temperature side temperature lowering position X_{L1} and the heating element 115. That is, the low temperature side temperature lowering position X_{L2} has a temperature lower than the high temperature side temperature lowering position X_{L1}.

Step S300 includes a step for moving the semiconductor substrate 10 from the high temperature side temperature lowering position X_{L1} to the low temperature side temperature lowering position X_{L2}, with a temperature lower than that of the high temperature side temperature lowering position X_{L1}. Step S300 may include a step for moving the semiconductor substrate 10 from the deposition position X_{D} to the high temperature side temperature lowering position X_{L1}, with a temperature lower than that of the deposition position X_{D}. Step S300 may include a step for moving the semiconductor substrate 10 from the low temperature side temperature lowering position X_{L2} to the extraction position X_{E2}, with a temperature lower than that of the low temperature side temperature lowering position X_{L2}.

In step S300, the semiconductor substrate 10 may be moved in the order of the deposition position X_{D}, the high temperature side temperature lowering position X_{L1}, the low temperature side temperature lowering position X_{L2}, and the extraction position X_{E2}. Thereby, the temperature of the semiconductor substrate 10 can be gradually lowered.

The step S300 includes lowering the temperature of the semiconductor substrate 10 by moving the semiconductor substrate 10 away from the heating element 115 that is heated to a predetermined temperature. Also in this case, the time for cooling the heating element 115 is not required, and therefore the temperature of the semiconductor substrate 10 can be lowered more quickly than in the case in which the temperature of the heating element 115 is changed.

In the manufacturing method of the semiconductor device 300, the distance between the semiconductor substrate 10 and the heating element 115 may be changed in at least one of the temperature raising step S100 or the temperature lowering step S300. In the temperature raising step S100, when the temperature of the semiconductor substrate 10 is raised by bringing the semiconductor substrate 10 close to the heating element 115, in the temperature lowering step S300, the temperature of the semiconductor substrate 10 may be lowered at the deposition position. In the temperature raising step S100, when the temperature of the semiconductor substrate 10 is raised at the deposition position, in the temperature lowering step S300, the temperature of the semiconductor substrate 10 may be lowered by moving the semiconductor substrate 10 away from the heating element 115.

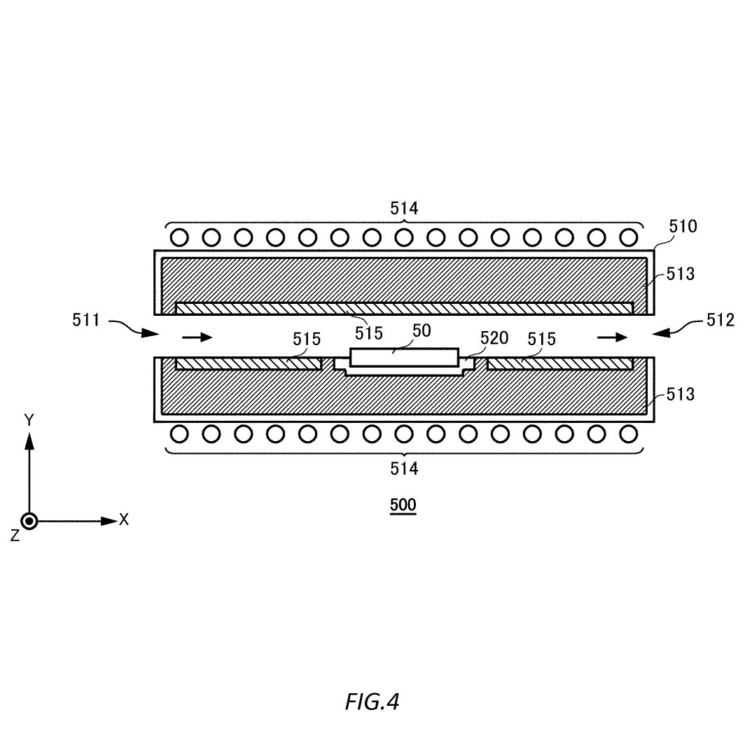

FIG. 4 shows an example of a cross-section of a manufacturing apparatus 500 of the semiconductor device 300 in a comparative example. The manufacturing apparatus 500 in the comparative example has a susceptor 520 for mounting a deposition chamber 510 and a semiconductor substrate 50. The manufacturing apparatus 500 of the comparative example does not have a configuration for changing the distance between the semiconductor substrate 50 and a heating element 515.

In the manufacturing apparatus 500 of the comparative example, the susceptor 520 to which the semiconductor substrate 50 is mounted is first arranged at a predetermined deposition position at a temperature that is equal to or less than the intake temperature. Then, by gradually raising the temperature of the heating element 515, the temperature of the semiconductor substrate 50 is raised to the deposition temperature. The heating element 515 may be heated by an inductive heating coil 514. In addition, the manufacturing apparatus 500 of the comparative example may also be provided with a thermal insulation material 513.

Subsequently, by introducing a carrier gas and a raw material gas from a gas introduction tube 511 in a state in which the temperature is raised to the deposition temperature, a semiconductor layer can be deposited on the semiconductor substrate 50. Also in the manufacturing apparatus 500 of the comparative example, the semiconductor substrate 50 may be rotated in an XZ plane. The carrier gas and the raw material gas are discharged to the outside of the deposition chamber 510 from the gas discharge pipe 512.

In the manufacturing apparatus 500 of the comparative example, after depositing the semiconductor layer, the heating element 515 is cooled. Thereby, the semiconductor substrate 50 is gradually cooled to have a temperature that is lowered to a temperature equal to or less than the extraction temperature. Then, the semiconductor substrate 50 on which a semiconductor layer whose temperature is lowered to a temperature equal to or less than the extraction temperature is deposited is extracted from the deposition chamber 510.

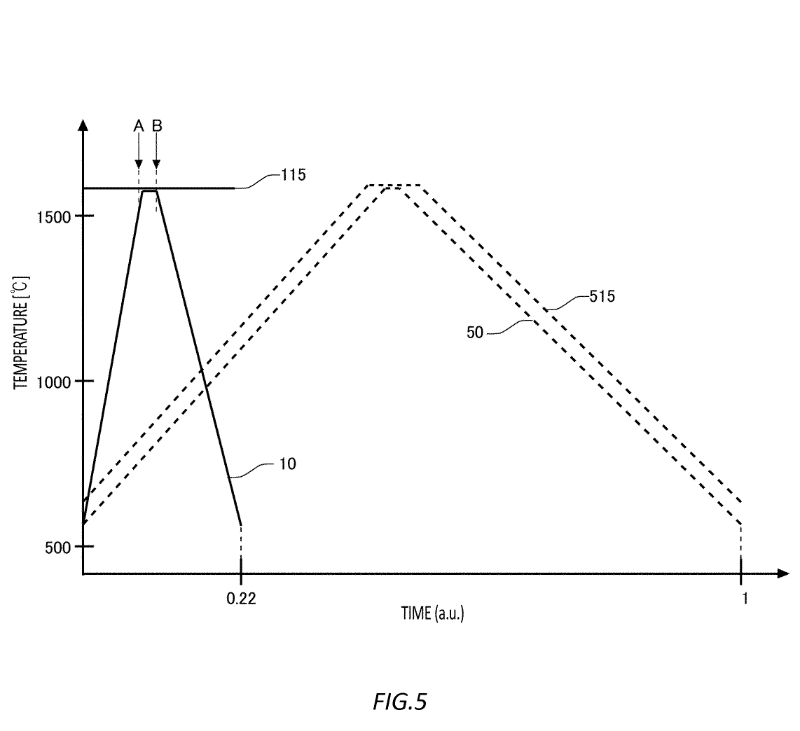

FIG. 5 shows the deposition time when each of the manufacturing apparatus 100 of the present example and the manufacturing apparatus 500 of the comparative example is used. FIG. 5 is a graph showing the temperature of the semiconductor substrate and the heating element on the vertical axis and the time on the horizontal axis. Note that, when using the manufacturing apparatus 500 of the comparative example, the time on the horizontal axis is normalized using the time for extracting the semiconductor substrate to which the semiconductor layer is deposited as a reference. In FIG. 5, the solid line shows a case in which the manufacturing apparatus 100 of the present example is used, and the dashed line shows a case in which the manufacturing apparatus 500 of the comparative example is used, respectively.

In the manufacturing apparatus 100 of the present example, the temperature of the heating element 115 is constant. In the manufacturing apparatus 500 of the comparative example, the deposition temperature is obtained by raising the temperature of the heating element 515 after placing the semiconductor substrate 50 at the deposition position, and the extraction temperature is obtained by lowering the temperature of the heating element 515 after depositing. In the present example, by making the temperature of the heating element 115 constant, energy for raising the temperature of the heating element and energy for lowering the temperature of the heating element can be reduced.

In the manufacturing apparatus 100 of the present example, by changing the distance between the heating element 115 with a constant temperature and a semiconductor substrate 10, the temperature of the semiconductor substrate 10 can be raised and lowered more rapidly than the manufacturing apparatus 500 of the comparative example. In the present example, the temperature raising rate in the temperature raising step may be 30℃/min or more, or 1000℃/min or less. The temperature lowering rate in the temperature lowering step may be 50℃/min or more, or 1000℃/min or less.

For the time required for depositing the semiconductor layer on the semiconductor substrate, there is no significant difference between the manufacturing apparatus 100 of the present example and the manufacturing apparatus 500 of the comparative example. The manufacturing apparatus 100 of the present example can shorten the time required for manufacturing the semiconductor substrate to which the semiconductor layer is deposited, by making the time required for raising and lowering the temperature of the semiconductor substrate 10 shorter than that of the manufacturing apparatus 500 of the comparative example.

In the manufacturing apparatus 100 of the present example, the temperature change in the semiconductor substrate 10 at the deposition position X_{D} is smaller than that of the manufacturing apparatus 500 of the comparative example. While in the manufacturing apparatus 500 of the comparative example, the temperature is raised from the intake temperature to the deposition temperature at the deposition position X_{D}, and lowered to the extraction temperature from the deposition temperature, in the manufacturing apparatus 100 of the present example, the temperature is raised in the process of moving from the intake position X_{E1} to the deposition position X_{D}, and immediately lowered to a temperature lower than the deposition temperature after reaching the deposition position X_{D} at the time point A, immediately reaching the deposition temperature, and then leaving the deposition position X_{D} at the time point B.

In an example, at least one of a temperature raising amount of the semiconductor substrate 10 in the temperature raising step S100 at the deposition position X_{D} or a temperature lowering amount of the semiconductor substrate 10 in the temperature lowering step S300 at the deposition position X_{D} is 50% or less of the temperature difference between the deposition temperature and the room temperature. At least one of the temperature raising amount or the temperature lowering amount may be 1/4 or less, 1/8 or less, or 1/16 or less of the temperature difference between the deposition temperature and the room temperature.

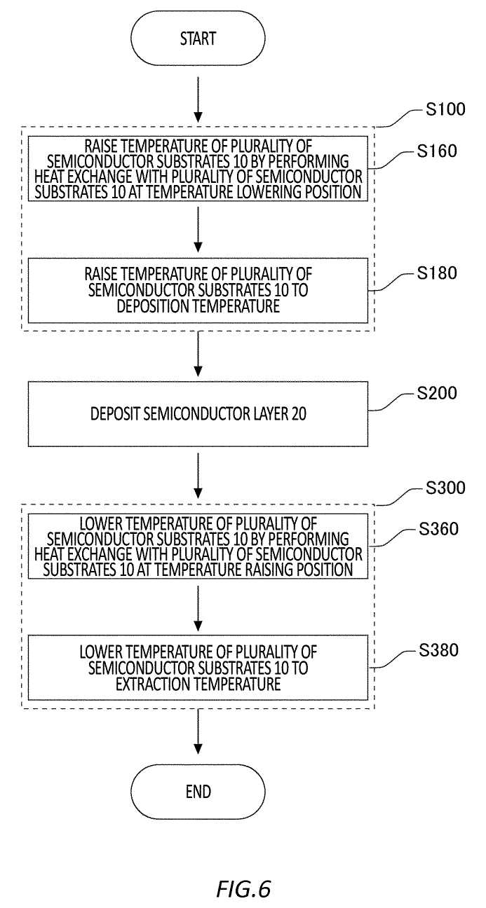

FIG. 6 is a modified example of the manufacturing method of the semiconductor device 300. In the example of FIG. 6, in the step S100, the temperature of each of the plurality of semiconductor substrates 10 is raised, and in the step S300, the temperature of each of the plurality of semiconductor substrates 10 is lowered. Description of step S200 that deposits the semiconductor layer 20 is omitted since it is similar to step S200 described so far, except that the semiconductor layer 20 is deposited on the plurality of semiconductor substrates 10.

In the modified example of the manufacturing method shown in FIG. 6, the difference from the manufacturing method described in FIG. 2A or the like is that heat exchange is performed between the plurality of semiconductor substrates 10. In at least one of the temperature raising step S100 or the temperature lowering step S300, the plurality of semiconductor substrates 10 positioned at the temperature raising position may be subjected to a heat exchange with the plurality of semiconductor substrates 10 positioned at the temperature lowering position.

The temperature raising step S100 may include step S160 that raises the temperature of each of the plurality of semiconductor substrates 10 positioned at the temperature raising position by performing a heat exchange with the plurality of semiconductor substrates 10 at the temperature lowering position. In step S160, the temperature of each of the plurality of semiconductor substrates 10 positioned at the temperature raising position is raised by supplying heat from the plurality of semiconductor substrates 10 positioned at the temperature lowering position. The temperature raising performed by the heat exchange may be performed more than two times. In step S160, the temperature of each of the plurality of semiconductor substrates 10 may be raised, at the temperature raising position, from the intake temperature to the first substrate temperature using the heat exchange.

In step S160, the temperature of each of the plurality of semiconductor substrates 10 may be raised to the first substrate temperature using a method other than the heat exchange. As an example, the temperature of each of the plurality of semiconductor substrates 10 is raised to the first substrate temperature at the temperature raising position using the temperature raising using an additional heating device after the temperature raising that is performed by the heat exchange.

Step S100 includes step S180 that raises the temperature of each of the plurality of semiconductor substrates 10 to the deposition temperature. Step S180 may be performed after step S160. The temperature of each of the plurality of semiconductor substrates 10 is raised to the first substrate temperature by step S160, and therefore the time required for the temperature raising to the deposition temperature in step S180 can be shortened. The temperature of each of the plurality of semiconductor substrates 10 in step S180 may be raised, at the deposition position, from the first substrate temperature to the deposition temperature using a heating element that heats the plurality of semiconductor substrates 10.

The temperature lowering step S300 may include step S360 that lowers the temperature of each of the plurality of semiconductor substrates 10 positioned at the temperature lowering position by performing heat exchange with the plurality of semiconductor substrates 10 at the temperature raising position. In step S360, the temperature of each of the plurality of semiconductor substrates 10 positioned at the temperature lowering position is lowered by supplying heat to the plurality of semiconductor substrates 10 positioned at the temperature raising position. The temperature lowering performed by the heat exchange may be performed more than two times.

The temperature lowering step S300 includes step S380 that lowers the temperature of each of the plurality of semiconductor substrates 10 to the extraction temperature. Step S380 may be performed after step S360. In step S380, the temperature of each of the plurality of semiconductor substrates 10 may be lowered to the extraction temperature using heat exchange, or may be lowered to the extraction temperature using an additional cooling apparatus.

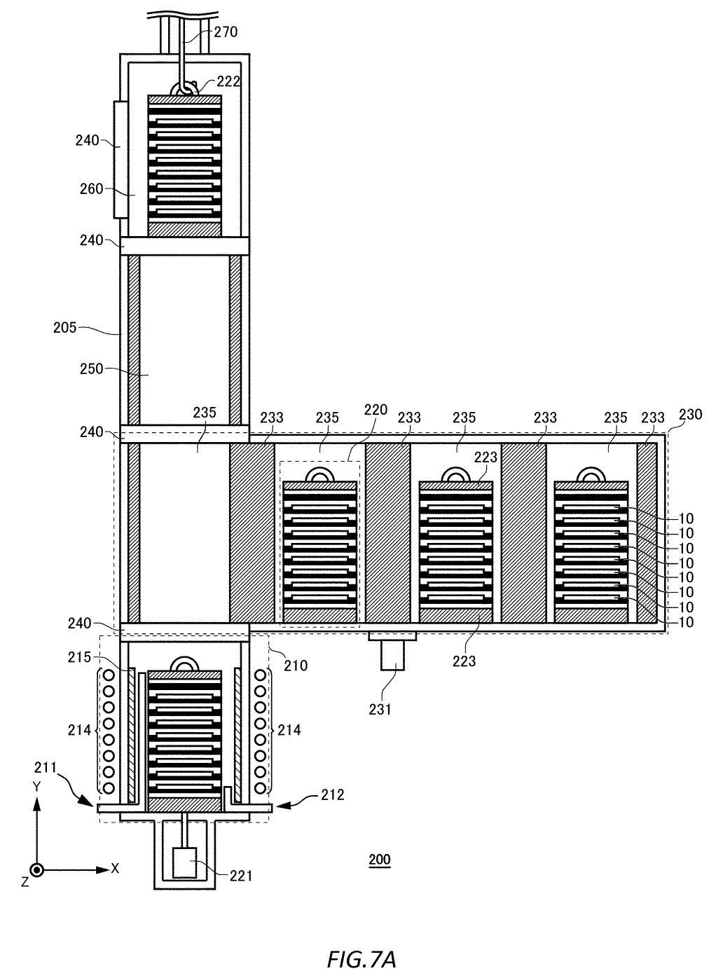

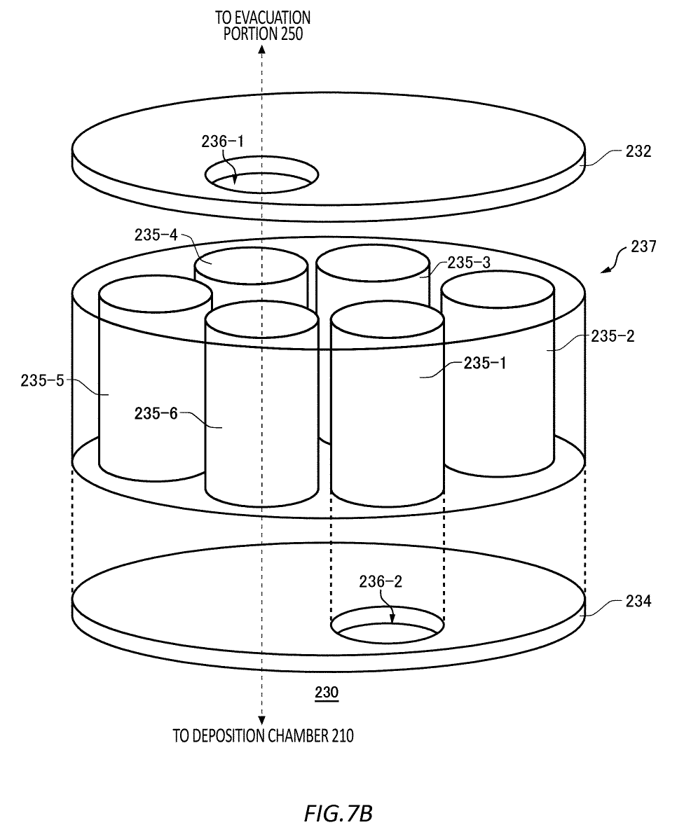

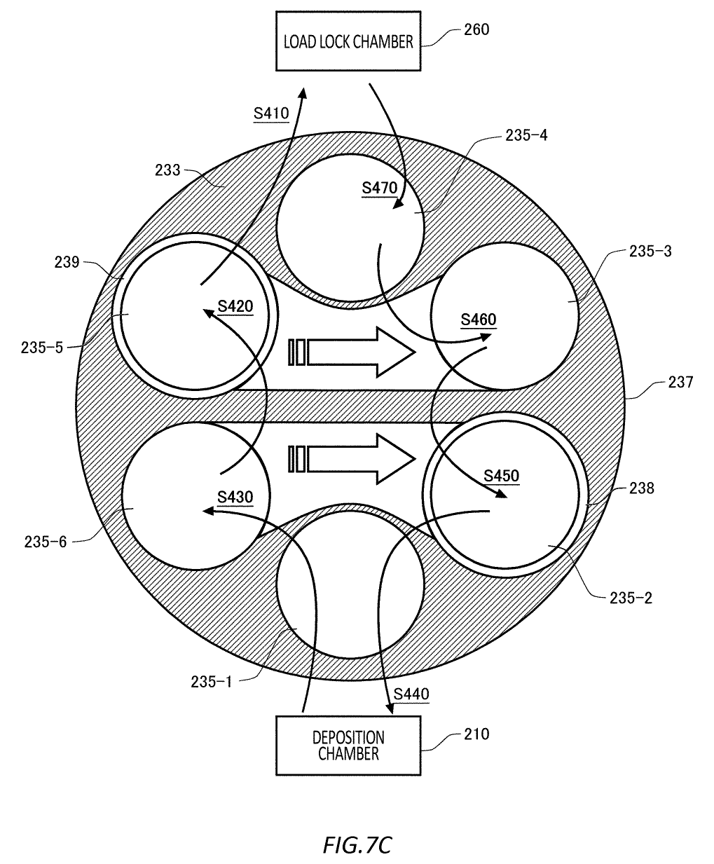

FIG. 7A shows a cross-sectional view of a manufacturing apparatus 200 of the semiconductor device 300. Similar to the manufacturing apparatus 100, an outer wall 205 of the manufacturing apparatus 200 is composed of a transparent quartz, an opaque quartz, or the like that is highly heat-resistant. The manufacturing apparatus 200 of the present example comprises a deposition chamber 210, a heat exchanging portion 230, a gate valve 240, an evacuation portion 250, a load lock chamber 260, and a boat moving mean 270. The deposition chamber 210 has a gas introduction tube 211, a gas discharge pipe 212, a inductive heating coil 214, and a heating element 215.

The deposition chamber 210 deposits a semiconductor layer 20 on the plurality of semiconductor substrates 10 at a predetermined deposition position. Inside the deposition chamber 210, a heating element 215 that raises the temperature of each of the plurality of semiconductor substrates 10 to a predetermined deposition temperature is provided. The heating element 215 may also be heated using an electromagnetic induction.

The manufacturing apparatus 200 houses a boat 220 for mounting the plurality of semiconductor substrates 10, and raises and lowers the temperature of the boat 220 and each of the plurality of semiconductor substrates 10. The boat 220 may have a thermal insulation material 223 at the upper portion and lower portion. In the example of FIG. 7A, the boat 220 is mounted with eight semiconductor substrates 10, but the number of semiconductor substrates 10 that can be mounted in the boat 220 is not limited thereto. The manufacturing apparatus 200 can deposit the semiconductor layer 20 at the same time on each of the plurality of semiconductor substrates 10 mounted on the boat 220, and can shorten the time required for depositing the semiconductor layer 20 compared to a case in which semiconductor layer 20 is deposited one by one.

In the deposition chamber 210, the semiconductor layer 20 can be deposited on the plurality of semiconductor substrates 10 by introducing a carrier gas and a raw material gas from the gas introduction tube 211 after raising the temperature of each of the plurality of semiconductor substrates 10 mounted on the boat 220 to the deposition temperature. The gas introduction tube 211 may be arranged along the boat 220 housed in the deposition chamber 210. Thereby, gas can be efficiently introduced to the plurality of semiconductor substrates 10 mounted on the boat 220. The carrier gas and the raw material gas are discharged to the outside of the deposition chamber 210 from the gas discharge pipe 212.

The deposition chamber 210 may have a boat rotary element 221 that rotates the boat 220 on which the plurality of semiconductor substrates 10 are mounted. The boat rotary element 221 rotates, in the XZ plane, the boat 220 on which the plurality of semiconductor substrates 10 are mounted. Thereby, the temperature irregularity of the plurality of semiconductor substrates 10 can be reduced, and the semiconductor layer 20 can be uniformly deposited.

A material of the boat rotary element 221 may be a material having a specific heat similar to that of the plurality of semiconductor substrates 10. Thereby, the temperature of the boat rotary element 221 can be set as a temperature similar to the substrate temperature of the plurality of semiconductor substrates 10, to improve the temperature raising and lowering speed. As an example, if each of the plurality of semiconductor substrates 10 is a silicon carbide semiconductor substrate, the boat rotary element 221 is composed of silicon carbide.

The heat exchanging portion 230 performs a heat exchange between the plurality of semiconductor substrates 10 having different temperatures. In the manufacturing apparatus 200 of the present example, also in the period of depositing the semiconductor layer 20 on the plurality of semiconductor substrates 10 in the deposition chamber 210, in the heat exchanging portion 230, the temperature of each of the plurality of semiconductor substrates 10 positioned at the temperature raising position can be raised by performing the heat exchange with the plurality of semiconductor substrates 10 positioned at the temperature lowering position. The manufacturing apparatus 200 of the present example can be shorten the temperature raising time in the deposition chamber 210 by preheating the plurality of semiconductor substrates 10 before moving the boat 220 to the deposition chamber 210.

The heat exchanging portion 230 is provided to have a cylindrical shape. The heat exchanging portion 230 includes a plurality of heat exchange chambers 235 for housing the boat 220 on which the plurality of semiconductor substrates 10 are mounted, a thermal insulation material 233 for thermal insulation between adjacent heat exchange chambers 235, and a heat exchanging portion rotary element 231 that rotates the heat exchanging portion 230. Heat exchange using the heat exchanging portion 230 will be specifically described below.

The gate valve 240 may be provided between the respective configurations. The gate valve 240 of the present example is provided between the deposition chamber 210 and the heat exchanging portion 230, between the heat exchanging portion 230 and the evacuation portion 250, between the evacuation portion 250 and the load lock chamber 260, and at an extraction position of the boat 220 in the load lock chamber 260. By opening and closing the gate valve 240, the boat 220 on which the plurality of semiconductor substrates 10 are mounted can move back and forth between respective configurations.

The evacuation portion 250 houses the boat 220. In the manufacturing apparatus 200, the boat 220 is moved between the heat exchanging portion 230 and the deposition chamber 210 via the evacuation portion 250. The boat 220 in which the plurality of semiconductor substrates 10 having the semiconductor layer 20 deposited thereon is mounted is moved to the evacuation portion 250 from the deposition chamber 210, and moved to the heat exchange chamber 235 of the heat exchanging portion 230 from the evacuation portion 250. The boat 220 in which the plurality of semiconductor substrates 10 on which the semiconductor layer 20 is not deposited is mounted is moved to the evacuation portion 250 from the heat exchange chamber 235 of the heat exchanging portion 230 and moved to the deposition chamber 210 from the evacuation portion 250.

In the manufacturing apparatus 200, the boat 220 is moved between different heat exchange chambers 235 of the heat exchanging portion 230 via the evacuation portion 250. As an example, the boat 220 is moved from the heat exchange chamber 235, which is the low temperature side temperature raising position, to the evacuation portion 250, and is moved from the evacuation portion 250 to the heat exchange chamber 235 which is the high temperature side temperature raising position. As an example, the boat 220 is moved from the heat exchange chamber 235, which is the high temperature side temperature lowering position, to the evacuation portion 250, and is moved from the evacuation portion 250 to the heat exchange chamber 235 which is the low temperature side temperature lowering position.

The evacuation portion 250 of the present example is provided above the heat exchanging portion 230, but the position at which the evacuation portion 250 is provided is not limited to the present example. The evacuation portion 250 may be provided below the heat exchanging portion 230, or may be adjacent to the heat exchanging portion 230. The evacuation portion 250 may be provided below the deposition chamber 210. When the boat 220 is moved between the deposition chamber 210 and the heat exchanging portion 230, the position at which the evacuation portion 250 is provided is not limited as long as the boat 220 can be housed therein.

The load lock chamber 260 extracts the boat 220 on which the plurality of semiconductor substrates 10 are mounted, which are subjected to the temperature lowering performed in the heat exchanging portion 230. The load lock chamber 260 may extract the plurality of semiconductor substrates 10, which are subjected to the temperature lowering to the extraction temperature in the heat exchanging portion 230. The load lock chamber 260 may extract the plurality of semiconductor substrates 10, which are subjected to the temperature lowering to the second substrate temperature in the heat exchanging portion 230, and lower the temperature to the extraction temperature inside the load lock chamber 260.

The load lock chamber 260 may extract the boat 220 in which the plurality of semiconductor substrates 10 having the semiconductor layer 20 deposited thereon is mounted, and alternatively, may house the boat 220 that is mounted with a plurality of semiconductor substrates 10 on which the semiconductor layer 20 is not deposited. Thereby, the deposition of the semiconductor layer 20 can be completed to sequentially extract the plurality of semiconductor substrates 10 after whose temperature is lowered to the extraction temperature, and can increase the manufacturing process throughput of the semiconductor device 300.

The boat moving mean 270 moves the boat 220 on which the plurality of semiconductor substrates 10 are mounted. The boat moving mean 270 of the present example is provided to have a hook shape. The boat moving mean 270 is illustrated using an aspect in which the boat 220 is movable up and down by hooking the boat 220 to the hanging portion 222 provided in the upper portion, but the present example is not limited thereto. The boat moving mean 270 may be robotic arm, a belt conveyor, or the like. There is no problem as long as the boat moving mean 270 is movable between the configurations of the manufacturing apparatus 200 of boat 220.

FIG. 7B is an example of the heat exchanging portion 230. FIG. 7B shows perspective view of the heat exchanging portion 230. In FIG. 7B, in terms of visibility, the thermal insulation material 233 that performs thermal insulation on the adjacent heat exchange chamber 235 is omitted. The heat exchanging portion 230 of the present example has six heat exchange chambers 235-1, 235-2, 235-3, 235-4, 235-5, and 235-6. The number of heat exchange chambers 235 included in the heat exchanging portion 230 is not limited thereto. The heat exchanging portion 230 may have five or fewer heat exchange chambers 235, or may have seven or more heat exchange chambers 235.

The heat exchanging portion 230 includes a body 237 including the plurality of heat exchange chambers 235, an upper member 232 that is provided at the upper portion of the body 237 and is fixed on the manufacturing apparatus 200, and a lower member 234 that is provided on the lower portion of the body 237 and that can rotate together with the body 237. In the upper member 232 and the lower member 234, a through hole 236-1 and a through hole 236-2 are provided, respectively.

Because the upper member 232 is fixed on the manufacturing apparatus 200, the upper member 232 does not rotate even if the body 237 rotates. Thus, the position of the through hole 236-1 provided on the upper member 232 does not change even if the body 237 rotates. The evacuation portion 250 and the load lock chamber 260 are provided above the through hole 236-1 that is provided on the upper member 232, and the deposition chamber 210 is provided below the through hole 236-1.

The heat exchange chamber 235 is provided to have a hollow cylindrical shape with its top and bottom portions open. If the body 237 rotates, the heat exchange chamber 235 is moved below the through hole 236-1, and the boat 220 can be taken into or out of the heat exchange chamber 235 from its upper side via the through hole 236-1.

Because the lower member 234 is rotated together with the body 237, the through hole 236-2 provided in the lower member 234 is also moved together with the rotation of the body 237. The through hole 236-2 provided in the lower member 234 of the present example is provided to be positioned below the heat exchange chamber 235-1 among the plurality of heat exchange chambers 235. Thus, if the body 237 is rotated, there is an aperture below the heat exchange chamber 235-1, and the part below each of the heat exchange chambers 235-2, 235-3, 235-4, 235-5, and 235-6 is a closed state.

The through hole 236-2 may be provided to be positioned below the heat exchange chamber other than the heat exchange chamber 235-1. The part below the heat exchange chamber provided with the through hole 236-2 is an aperture. Thereby, the boat 220 can be moved to the deposition chamber 210 via the heat exchange chamber provided with the through hole 236-2.

The part below the heat exchange chamber in which the through hole 236-2 is not provided below the heat exchange chamber is closed. Thereby, the boat 220 can be housed in the heat exchange chamber that is not provided with the through hole 236-2 below the heat exchange chamber.

In the example of FIG. 7B, above the heat exchange chamber 235-6, there is an aperture with the through hole 236-1, and there is an aperture with the through hole 236-2 below the heat exchange chamber 235-1. Thus, the boat 220 housed in the heat exchange chamber 235-6 can be moved to the evacuation portion 250 via the through hole 236-1. Subsequently, for example, the body 237 is rotated clockwise in a top view, to align the position of each of the through hole 236-1, the heat exchange chamber 235-1, and the through hole 236-2. At this time, the boat 220 housed in the evacuation portion 250 can be moved to the deposition chamber 210 via the through hole 236-1, the heat exchange chamber 235-1, and the through hole 236-2.

FIG. 7C is a schematic diagram of the heat exchanging portion 230 in a top view. With reference to FIG. 7C, the heat exchange using the heat exchanging portion 230 is described. In the example of FIG. 7C, the heat exchange chamber 235-1 is empty, and a boat 220 having a plurality of semiconductor substrates 10 mounted thereon is housed in each of the heat exchange chamber 235-2 to the heat exchange chamber 235-6. Also, the semiconductor layer 20 is deposited on the plurality of semiconductor substrates 10 in the deposition chamber 210.

In step S410, the plurality of semiconductor substrates 10 housed in the heat exchange chamber 235-5 is moved to the load lock chamber 260 via the evacuation portion 250. Thereby, the plurality of semiconductor substrates 10 on which the semiconductor layer 20 is deposited and whose temperature is lowered to the extraction temperature can be extracted from the load lock chamber 260. After step S410, the heat exchange chamber 235-5 becomes empty. Subsequently, the boat 220 is moved from another configuration to the empty heat exchange chamber 235.

In step S420, the plurality of semiconductor substrates 10 housed in the heat exchange chamber 235-6 is moved to the heat exchange chamber 235-5 via the evacuation portion 250. After step S420, the heat exchange chamber 235-6 becomes empty.

In step S430, the plurality of semiconductor substrates 10 with the semiconductor layer 20 deposited thereon in the deposition chamber 210 is moved to the heat exchange chamber 235-6 via the evacuation portion 250. The substrate temperature of the plurality of semiconductor substrates 10 housed in the heat exchange chamber 235-6 may be higher than the substrate temperature of the plurality of semiconductor substrates 10 moved to the heat exchange chamber 235-5 in step S420. That is, the heat exchange chamber 235-6 may be a high temperature side temperature lowering position, and the heat exchange chamber 235-5 may be a low temperature side temperature lowering position with a temperature lower than that of the high temperature side temperature lowering position.

In step S440, the plurality of semiconductor substrates 10 housed in the heat exchange chamber 235-2 are moved to the deposition chamber 210 via the evacuation portion 250. The temperature of each of the plurality of semiconductor substrates 10 housed in the heat exchange chamber 235-2 may be raised to a first substrate temperature when the plurality of semiconductor substrates 10 are moved to the deposition chamber 210. After step S440, the heat exchange chamber 235-2 becomes empty.

In step S450, the plurality of semiconductor substrates 10 housed in the heat exchange chamber 235-3 is moved to the heat exchange chamber 235-2 via the evacuation portion 250. After step S450, the heat exchange chamber 235-3 becomes empty. After step S450, as shown with a hollow-out arrow in FIG. 7C, the temperature of each of the plurality of semiconductor substrates 10 positioned at the heat exchange chamber 235-6 that is the high temperature side temperature lowering position is lowered by supplying heat to the plurality of semiconductor substrates 10 moved to the heat exchange chamber 235-2 in step S450. That is, the heat exchange chamber 235-2 is a high temperature side temperature raising position.

The temperature of each of the plurality of semiconductor substrates 10 positioned in the heat exchange chamber 235-2, which is the high temperature side temperature raising position, is raised by supplying heat from the plurality of semiconductor substrates 10 positioned in the heat exchange chamber 235-6, which is the high temperature side temperature lowering position. In this process, the temperature of each of the plurality of semiconductor substrates 10 housed in the heat exchange chamber 235-2 may be raised to the first substrate temperature.

The heating device 238 may be provided in the heat exchange chamber 235-2, which is the high temperature side temperature raising position. The temperature of each of the plurality of semiconductor substrates 10 housed in the heat exchange chamber 235-2, which is the high temperature side temperature raising position, may be raised to the first substrate temperature by the heating device 238 after the temperature raising is performed by a heat exchange.

In step S460, the plurality of semiconductor substrates 10 housed in the heat exchange chamber 235-4 is moved to the heat exchange chamber 235-3 via the evacuation portion 250. Herein, the temperature of each of the plurality of semiconductor substrates 10 moved to the heat exchange chamber 235-2 in step S450 immediately before is raised by a previous heat exchange cycle, and therefore, has a temperature higher than that of each of the plurality of semiconductor substrates 10 moved to the heat exchange chamber 235-3 in step S460. That is, the heat exchange chamber 235-3 is a low temperature side temperature raising position with a temperature lower than that of the heat exchange chamber 235-2. After step S460, the heat exchange chamber 235-4 becomes empty.

After step S460, as shown with a hollow-out arrow in FIG. 7C, the temperature of each of the plurality of semiconductor substrates 10 positioned at the heat exchange chamber 235-5 that is the low temperature side temperature lowering position is lowered by supplying heat to the plurality of semiconductor substrates 10 positioned at the heat exchange chamber 235-2, which is the low temperature side temperature raising position. In this process, the temperature of each of the plurality of semiconductor substrates 10 housed in the heat exchange chamber 235-5 may be lowered to the extraction temperature.

The cooling apparatus 239 may be provided in the heat exchange chamber 235-5, which is the low temperature side temperature lowering position. The temperature of each of the plurality of semiconductor substrates 10 housed in the heat exchange chamber 235-5 may be lowered to the extraction temperature by the cooling apparatus 239 after the temperature lowering is performed to the second substrate temperature by a heat exchange.

The temperature of each of the plurality of semiconductor substrates 10 positioned in the heat exchange chamber 235-3, which is the low temperature side temperature raising position, is raised by supplying heat from the plurality of semiconductor substrates 10 positioned in the heat exchange chamber 235-5, which is the low temperature side temperature lowering position. As show in FIG. 7C, the thermal insulation material 233 included in the heat exchanging portion 230 performs a heat exchange between the opposing heat exchange chambers, rather than adjacent heat exchange chambers.

In step S470, the plurality of semiconductor substrates 10 housed in the load lock chamber 260 is moved to the heat exchange chamber 235-4 via the evacuation portion 250. Thereby, the load lock chamber 260 becomes empty, and in step S410, the plurality of semiconductor substrates 10 housed in the heat exchange chamber 235-5 is movable to the load lock chamber 260.

In the manufacturing apparatus 200 of the present example, the temperature of each of the plurality of semiconductor substrates 10 loaded from the load lock chamber 260 is raised to the first substrate temperature from the intake temperature by moving the each of the plurality of semiconductor substrates 10 among the heat exchange chambers 235 of the heat exchanging portion 230. Subsequently, the plurality of semiconductor substrates 10 subjected to the temperature raising to the first substrate temperature are moved to the deposition chamber 210, and the semiconductor layer 20 is deposited after the temperature raising to the deposition temperature. Thereby, the time required for the temperature raising in the deposition chamber 210 is reduced, and therefore the time required for the process of depositing the semiconductor layer 20 can be shortened.

In the manufacturing apparatus 200 of the present example, the temperature of each of the plurality of semiconductor substrates 10 extracted from the deposition chamber 210 is lowered to the extraction temperature by moving the each of the plurality of semiconductor substrates 10 among the heat exchange chambers 235 of the heat exchanging portion 230. In a step of lowering the temperature of each of the plurality of semiconductor substrates 10, the temperature of each of the plurality of semiconductor substrates 10 housed in different heat exchange chambers 235 can be raised, and the energy required for the temperature raising of the plurality of semiconductor substrates 10 can be reduced.

The heat exchanging portion 230 is not limited to the aspects described from FIG. 7A to FIG. 7C. The heat exchanging portion 230 may be implemented in the aspect in which the heat exchange chambers 235 are arranged in one row or two rows, or may be implemented in the aspect in which the heat exchange chambers 235 are arranged in two stages in an up and down direction.

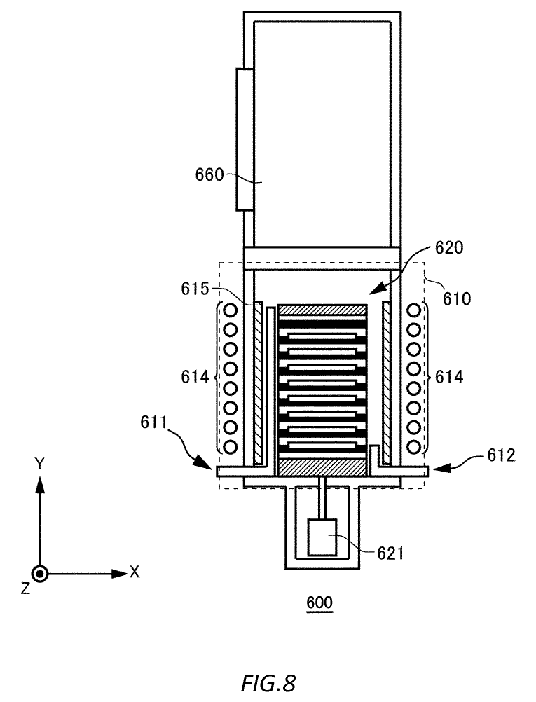

FIG. 8 shows an example of a cross-section of a manufacturing apparatus 600 of the semiconductor device 300 in a comparative example. The manufacturing apparatus 600 of the comparative example comprises a deposition chamber 610, a boat 620 on which a plurality of semiconductor substrates are mounted, and a housing chamber 660 housing the boat 620. The manufacturing apparatus 600 of the comparative example does not have a configuration for performing heat exchange of the plurality of semiconductor substrates.

In the manufacturing apparatus 600 of the comparative example, the boat 620 to which the plurality of semiconductor substrates are mounted is first arranged at a predetermined deposition position at a temperature that is equal to or less than the intake temperature. Then, by gradually raising the temperature of the heating element 615, the temperature of each of the plurality of semiconductor substrates is raised to the deposition temperature. The heating element 615 may be heated by an inductive heating coil 614.

Subsequently, by introducing a carrier gas and a raw material gas from a gas introduction tube 611 in a state in which the temperature is raised to the deposition temperature, a semiconductor layer can be deposited on the plurality of semiconductor substrates. Also in the manufacturing apparatus 600 of the comparative example, the boat 620 may be rotated in an XZ plane by a boat rotary element 621. The carrier gas and the raw material gas are discharged to the outside of the deposition chamber 610 from the gas discharge pipe 612.

In the manufacturing apparatus 600 of the comparative example, after depositing the semiconductor layer, the temperature of each of the plurality of semiconductor substrates is lowered to a temperature equal to or less than the extraction temperature inside the deposition chamber 610. Then, the plurality of semiconductor substrates subjected to the temperature lowering to the temperature equal to or less than the extraction temperature is extracted to the housing chamber 660 from the deposition chamber 610.

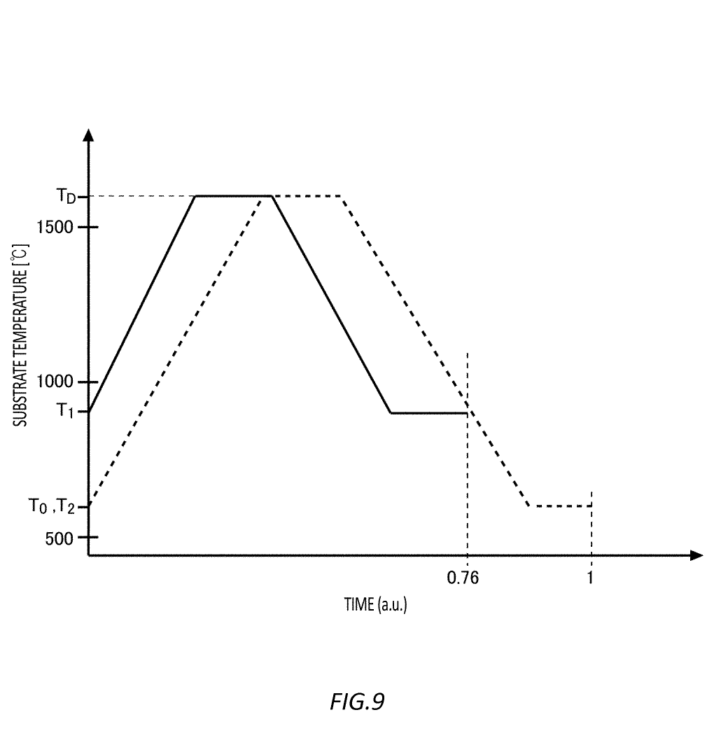

FIG. 9 shows the deposition time when each of the manufacturing apparatus 200 of the present example and the manufacturing apparatus 600 of the comparative example is used. FIG. 9 is a graph showing the temperature of the semiconductor substrate on the vertical axis and the time on the horizontal axis. Note that, when using the manufacturing apparatus 600 of the comparative example, the time on the horizontal axis is normalized using the time for extracting the semiconductor substrate to which the semiconductor layer is deposited as a reference from the deposition chamber. In FIG. 9, the solid line shows a case in which the manufacturing apparatus 200 of the present example is used, and the dashed line shows a case in which the manufacturing apparatus 600 of the comparative example is used, respectively.

The manufacturing apparatus 200 of the present example raises the temperature of each of the plurality of semiconductor substrates 10 to a first substrate temperature T₁ higher than an intake temperature T₀by the heat exchanging portion 230 before moving the plurality of semiconductor substrates 10 to the deposition chamber 210. Thus, when the deposition temperature T_{D} is the same, and the thermal conductivity of each of the plurality of semiconductor substrates 10 and the boat 220 is the same, the manufacturing apparatus 200 of the present example that raises the temperature from a first substrate temperature T₁ that is higher than the intake temperature T₀ to the deposition temperature T_{D} can raise the temperature of each of the plurality of semiconductor substrates 10 to the deposition temperature T_{D} in a shorter amount of time than that of the manufacturing apparatus 600 in the comparative example that raises the temperature from the intake temperature T₀ to the deposition temperature T_{D}.

In the manufacturing apparatus 200 of the present example, the temperature of each of the plurality of semiconductor substrates 10 with the semiconductor layer 20 deposited thereon is lowered to an extraction temperature T₂ by supplying heat to a different plurality of semiconductor substrates 10 by the heat exchanging portion 230. Therefore, the manufacturing apparatus 200 of the present example can move the plurality of semiconductor substrates 10 from the deposition chamber 210 to the heat exchanging portion 230 in the first substrate temperature T₁that is higher than the extraction temperature T₂. That is, the manufacturing apparatus 200 of the present example can reuse the deposition chamber 210 in a shorter amount of time than that of the manufacturing apparatus 600 of the comparative example. Note that, the example in which the intake temperature T₀ and the extraction temperature T₂ are the same is shown in FIG. 9, but the intake temperature T₀ and the extraction temperature T₂ may be temperatures different from each other.

In the manufacturing apparatus 200 of the present example, as the temperature difference between the first substrate temperature T₁ and the deposition temperature T_{D} becomes smaller, the time required for manufacturing the plurality of semiconductor substrates 10 with the semiconductor layer 20 stacked thereon can be shortened. The first substrate temperature T₁ is equal to or less than the heatproof temperature of a material configuring the boat moving mean 270. Thereby, the first substrate temperature T₁ can be set to be a temperature as high as possible.

In the manufacturing apparatus 200 of the present example, at least one of a temperature raising amount of the semiconductor substrate 10 in the temperature raising step S100 at the deposition chamber 210, that is, the deposition position or a temperature lowering amount of the semiconductor substrate 10 in the temperature lowering step S300 at the deposition position is 50% or less of the temperature difference between the deposition temperature T_{D} and the room temperature. For example, if the deposition temperature T_{D} is 1600℃, the first substrate temperature T₁ is 900℃, and the room temperature is 27℃, both the temperature raising amount and the temperature lowering amount are 700℃, and the temperature difference between the deposition temperature T_{D} and the room temperature is 50% or less of 1573℃.

By increasing the first substrate temperature T₁, the temperature raising amount and the temperature lowering amount at the deposition position can be decreased. At least one of the temperature raising amount or the temperature lowering amount may be 1/4 or less, 1/8 or less, or 1/16 or less of the temperature difference between the deposition temperature T_{D} and the room temperature.

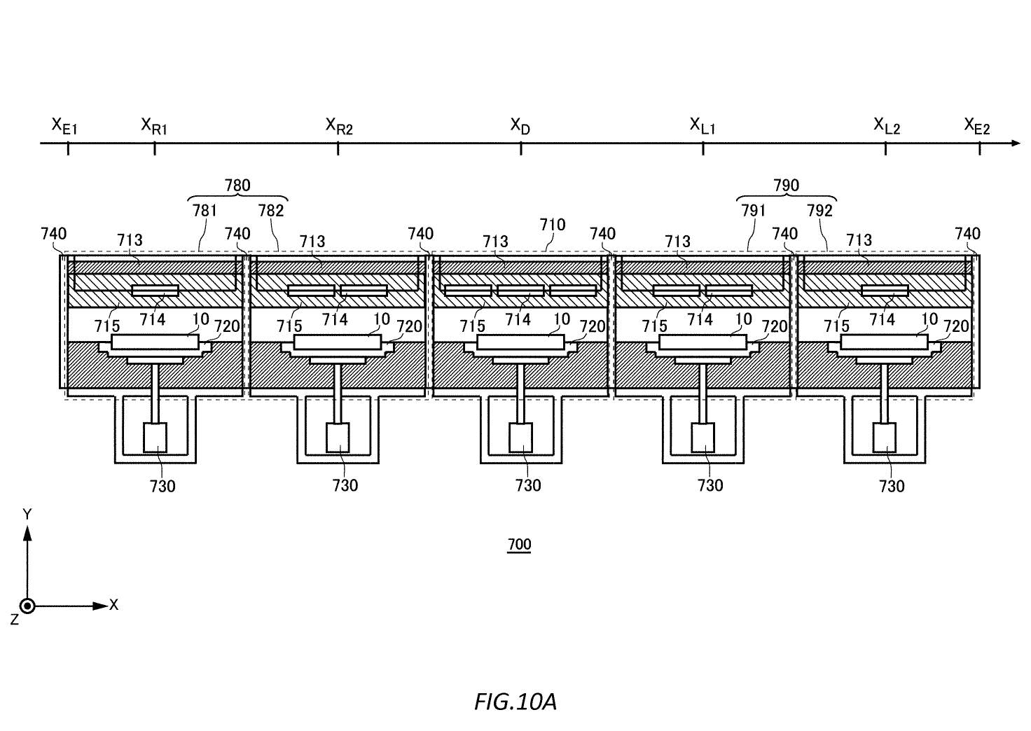

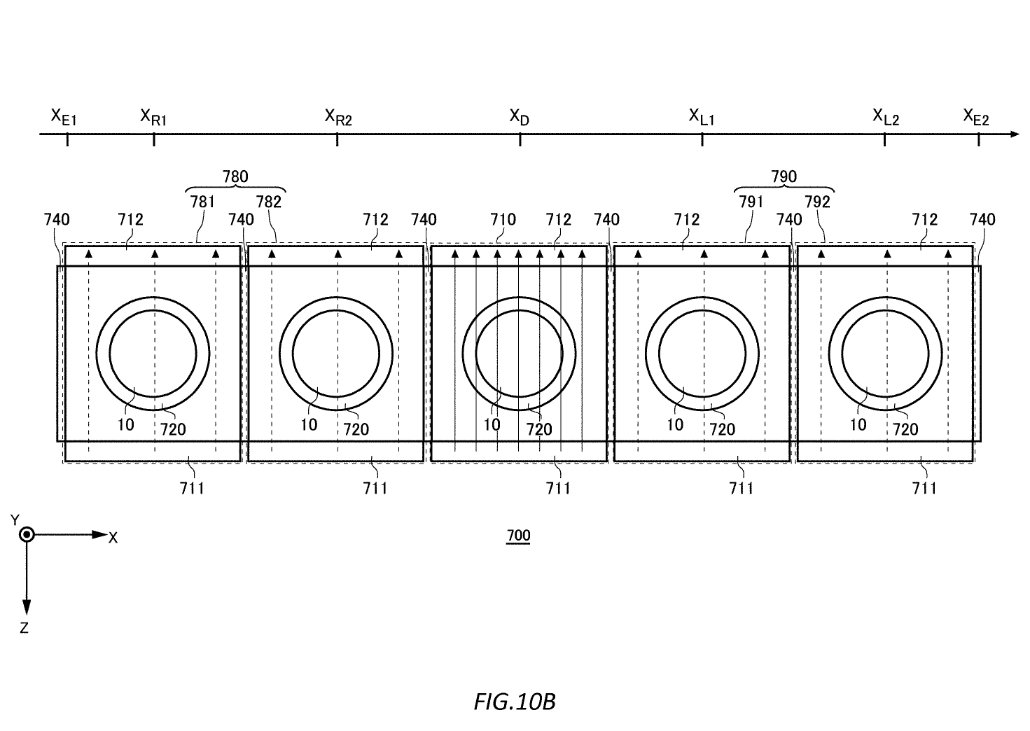

FIG. 10A shows a cross-sectional view of a manufacturing apparatus 700 of the semiconductor device 300. The manufacturing apparatus 700 of the present example comprises a deposition chamber 710, a rotary lifting element 730, a gate valve 740, a temperature raising portion 780, and a temperature lowering portion 790. The deposition chamber 710, the temperature raising portion 780, and the temperature lowering portion 790 have a gas introduction tube 711, a gas discharge pipe 712, and a heating element 715. The gas introduction tube 711 and the gas discharge pipe 712 are described below.

The deposition chamber 710 deposits a semiconductor layer 20 on the semiconductor substrate 10 at a predetermined deposition position X_{D}. Inside the deposition chamber 710, a heating element 715 that raises the temperature of the semiconductor substrate 10 to a predetermined deposition temperature is provided. The heating element 715 is covered with a thermal insulation material 713. The heating element 715 is heated by a heater 714. The heating element 715 may be heated by an electromagnetic induction.

The thermal insulation material 713 is provided inside the manufacturing apparatus 700. The thermal insulation material 713 may be provided inside the deposition chamber 710, the temperature raising portion 780, and the temperature lowering portion 790, and the thermal insulation material 713 may be provided between the inner wall of the manufacturing apparatus 700 and the heating element 715. Thereby, the interior of the manufacturing apparatus 700 can be efficiently heated without leaking heat generated by the heating element 715 to the outside.

The temperature raising portion 780 raises the temperature of each of the semiconductor substrate 10 and the susceptor 720. The temperature raising portion 780 is a temperature raising position. The temperature raising portion 780 has a heating element 715 for heating the semiconductor substrate 10 and the susceptor 720. The temperature of each of the semiconductor substrate 10 and the susceptor 720 is raised to the first substrate temperature from the intake temperature at the temperature raising portion 780.

The temperature raising portion 780 of the present example is composed of two temperature raising chambers separated by the gate valve 740, but not limited thereto. The temperature raising portion 780 may be composed of one temperature raising chamber, or may be composed of three or more temperature raising chambers. The temperature raising portion 780 of the present example includes a low temperature side temperature raising chamber 781 and a high temperature side temperature raising chamber 782. The temperature raising portion 780 may include a load lock chamber.

The low temperature side temperature raising chamber 781 is a temperature raising chamber with a temperature lower than that of the high temperature side temperature raising chamber 782. The temperature inside the low temperature side temperature raising chamber 781 of the present example is higher than the intake temperature and lower than the first substrate temperature. The temperature inside the low temperature side temperature raising chamber 781 may also be the intake temperature.

The high temperature side temperature raising chamber 782 is a temperature raising chamber with a temperature higher than that of the low temperature side temperature raising chamber 781 and with a temperature lower than that of the deposition chamber 710. The temperature inside the high temperature side temperature raising chamber 782 of the present example is higher than the intake temperature and lower than the deposition temperature. The temperature inside the high temperature side temperature raising chamber 782 may be the first substrate temperature. The high temperature side temperature raising chamber 782 is provided closer to the deposition chamber 710 than the low temperature side temperature raising chamber 781.

In the manufacturing apparatus 700 of the present example, the low temperature side temperature raising chamber 781, the high temperature side temperature raising chamber 782, and the deposition chamber 710 are arranged in this order. The low temperature side temperature raising chamber 781 and the high temperature side temperature raising chamber 782 correspond to the low temperature side temperature raising position X_{R1} and the high temperature side temperature raising position X_{R2}, respectively.

The low temperature side temperature raising chamber 781, the high temperature side temperature raising chamber 782, and the deposition chamber 710 have temperatures different from each other. The low temperature side temperature raising chamber 781, the high temperature side temperature raising chamber 782, and the deposition chamber 710 may have a different number of heaters 714. The high temperature side temperature raising chamber 782 may have the heaters 714, whose quantity is greater than that of the low temperature side temperature raising chamber 781, and the deposition chamber 710 may have heaters 714, whose quantity is greater than that of the high temperature side temperature raising chamber 782. Thereby, a temperature distribution in which the temperature increases from the low temperature side temperature raising chamber 781 to the deposition chamber 710 can be formed. In the present example, the number of heaters 714 included in the low temperature side temperature raising chamber 781, the high temperature side temperature raising chamber 782, and the deposition chamber 710 is one, two, and three, respectively.

The low temperature side temperature raising chamber 781, the high temperature side temperature raising chamber 782, and the deposition chamber 710 may include the same number of heaters 714. Then, heaters 714 provided in the low temperature side temperature raising chamber 781, the high temperature side temperature raising chamber 782, and the deposition chamber 710 may be set to different heater outputs, or may be different types of heaters.

The semiconductor substrate 10 and the susceptor 720 move between adjacent rooms by using a rotary lifting element 730 and a transport arm or the like that is not illustrated. The rotary lifting element 730 can move in a vertical direction or rotate the semiconductor substrate 10 and the susceptor 720. In the manufacturing apparatus 700 of the present example, the semiconductor substrate 10 and the susceptor 720 move to the low temperature side temperature raising chamber 781, the high temperature side temperature raising chamber 782, and the deposition chamber 710 in this order. Thereby, the temperature of each of the semiconductor substrate 10 and the susceptor 720 can be gradually raised.

The temperature lowering portion 790 lowers the temperature of each of the semiconductor substrate 10 and the susceptor 720. The temperature lowering portion 790 is a temperature lowering position. The temperature of each of the semiconductor substrate 10 and the susceptor 720 is lowered to an extraction temperature from the deposition temperature at the temperature lowering portion 790.

The temperature lowering portion 790 of the present example is composed of two temperature lowering chambers separated by the gate valve 740, but not limited thereto. The temperature lowering portion 790 may be composed of one temperature lowering chamber, or may be composed of three or more temperature lowering chambers. The temperature lowering portion 790 of the present example includes a high temperature side temperature lowering chamber 791 and a low temperature side temperature lowering chamber 792. The temperature lowering portion 790 may include a load lock chamber.

The high temperature side temperature lowering chamber 791 is a temperature lowering chamber with a temperature higher than that of the low temperature side temperature lowering chamber 792 and with a temperature lower than that of the deposition chamber 710. The temperature inside the high temperature side temperature lowering chamber 791 of the present example is higher than the extraction temperature and lower than the deposition temperature. The temperature inside the high temperature side temperature lowering chamber 791 may be the second substrate temperature. The high temperature side temperature lowering chamber 791 is provided closer to the deposition chamber 710 than the low temperature side temperature lowering chamber 792.

The low temperature side temperature lowering chamber 792 is a temperature lowering chamber with a temperature lower than that of the high temperature side temperature lowering chamber 791. The temperature inside the low temperature side temperature lowering chamber 792 of the present example is higher than the extraction temperature and lower than the second substrate temperature. The temperature inside the low temperature side temperature lowering chamber 792 may also be the extraction temperature.

In the manufacturing apparatus 700 of the present example, the deposition chamber 710, the high temperature side temperature lowering chamber 791, and the low temperature side temperature lowering chamber 792 are arranged in this order. The high temperature side temperature lowering chamber 791 and the low temperature side temperature lowering chamber 792 correspond to the high temperature side temperature lowering position X_{L1} and the low temperature side temperature lowering position X_{L2}, respectively.

The deposition chamber 710, the high temperature side temperature lowering chamber 791, and the low temperature side temperature lowering chamber 792 have temperatures different from each other. The deposition chamber 710, the high temperature side temperature lowering chamber 791, and the low temperature side temperature lowering chamber 792 may have a different number of heaters 714. The high temperature side temperature lowering chamber 791 may have heaters 714, whose quantity is less than that of the deposition chamber 710, and the low temperature side temperature lowering chamber 792 may have heaters 714, whose quantity is less than that of the high temperature side temperature lowering chamber 791. Thereby, a temperature distribution in which the temperature decreases from the deposition chamber 710 to the low temperature side temperature lowering chamber 792 can be formed. In the present example, the number of heaters 714 included in the deposition chamber 710, the high temperature side temperature lowering chamber 791, and the low temperature side temperature lowering chamber 792 is three, two, and one, respectively.

Similar to the temperature raising portion 780, the temperature lowering portion 790 may also have the same number of heaters 714. Then, by adjusting the output or the type of the heater 714, a similar effect can be obtained.

In the manufacturing apparatus 700 of the present example, the semiconductor substrate 10 and the susceptor 720 move to the deposition chamber 710, the high temperature side temperature lowering chamber 791, and the low temperature side temperature lowering chamber 792 in this order. Thereby, the temperature of each of the semiconductor substrate 10 and the susceptor 720 can be gradually lowered.

In the manufacturing apparatus 700 of the present example, by moving the semiconductor substrate 10 and the susceptor 720 between rooms, the temperature of the semiconductor substrate 10 is changed. Thereby, energy for raising the temperature of the heating element and energy for lowering the temperature of the heating element can be reduced.

In the manufacturing apparatus 700 of the present example, step S100 that raises the temperature of the semiconductor substrate 10 includes a step for moving the semiconductor substrate 10 between the plurality of temperature raising chambers included in the temperature raising portion 780, and between the temperature raising chamber and the deposition chamber 710. That is, the step for moving includes changing the position of the semiconductor substrate 10 relative to the deposition position X_{D}. In the present specification, changing the position of the semiconductor substrate 10 relative to the deposition position X_{D} is changing the distance between the semiconductor substrate 10 and the deposition position X_{D}.

In the manufacturing apparatus 700 of the present example, step S300 that lowers the temperature of the semiconductor substrate 10 includes a step for moving the semiconductor substrate 10 between the plurality of temperature lowering chambers included in the temperature lowering portion 790, and between the temperature lowering chamber and the deposition chamber 710. That is, the step for moving includes changing the position of the semiconductor substrate 10 relative to the deposition position X_{D}.

FIG. 10B shows an example of the manufacturing apparatus 700. FIG. 10B is an example of the manufacturing apparatus 700 in a top view. With reference to FIG. 10B, a gas flow inside the manufacturing apparatus 700 is described. Note that, in FIG. 10B, only configurations required for the description are illustrated, and descriptions of the other configurations are omitted.

The manufacturing apparatus 700 comprises a gas introduction tube 711 and a gas discharge pipe 712. The gas introduction tube 711 and the gas discharge pipe 712 are provided in the deposition chamber 710, the temperature raising portion 780, and the temperature lowering portion 790. The gas introduction tube 711 introduces one or more gases selected from a carrier gas, a raw material gas, or an inert gas into the chamber. The introduced gas is discharged from the gas discharge pipe 712 to the outside.

In the manufacturing apparatus 700 of the present example, in the temperature raising portion 780 and the temperature lowering portion 790, the inert gas may be introduced. In FIG. 10B, the flow of the inert gas is indicated with an arrow of a dashed line. The inert gas is a gas that does not react with the semiconductor substrate 10. The inert gas may be a noble gas. The inert gas may be any of nitrogen or argon. The inert gas is argon, as an example. In the temperature raising portion 780 and the temperature lowering portion 790, only the carrier gas may be introduced.

In the manufacturing apparatus 700 of the present example, in the deposition chamber 710, a gaseous mixture composed of the carrier gas and the raw material gas is introduced. In FIG. 10B, the flow of the gas mixture is indicated with an arrow of a solid line. Thereby, inside the deposition chamber 710, the semiconductor layer 20 can be deposited on the semiconductor substrate 10.

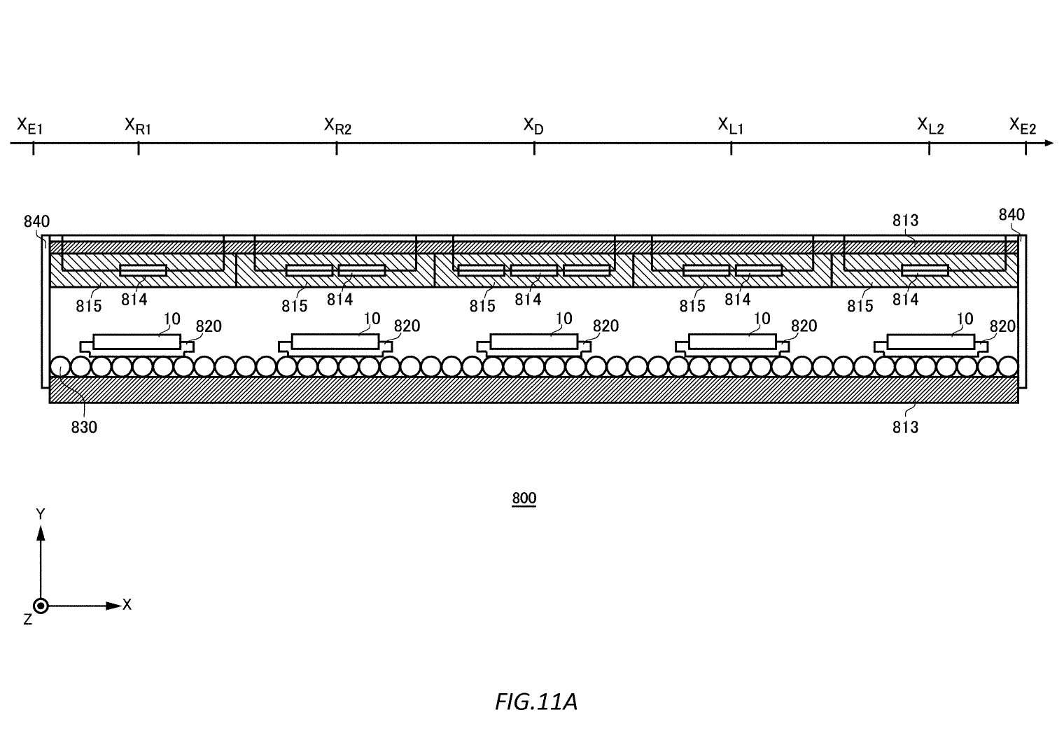

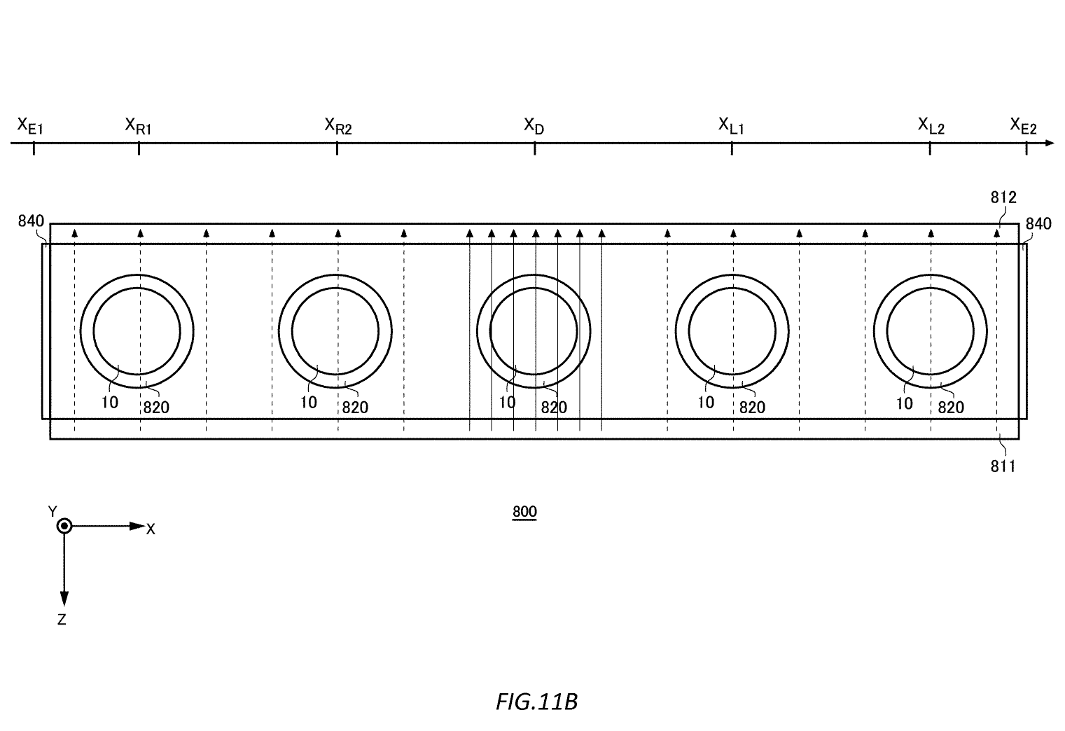

FIG. 11A shows a cross-sectional view of a manufacturing apparatus 800 of the semiconductor device 300. The manufacturing apparatus 800 of the present example comprises a susceptor moving portion 830 and a gate valve 840. The manufacturing apparatus 800 may comprise a gas introduction tube 811 and a gas discharge pipe 812 described below. The manufacturing apparatus 800 of the present example is different from the manufacturing apparatus 700 shown in FIG. 10A in that the temperature raising portion, the temperature lowering portion, and the deposition chamber are not partitioned with the gate valve.

The susceptor moving portion 830 moves the susceptor 820 on which the semiconductor substrate 10 is mounted. In the present example, the susceptor moving portion 830 is illustrated in the form of a roller, but it is not limited thereto. There is no problem as long as the susceptor moving portion 830 can move the susceptor 820 on which the semiconductor substrate 10 is mounted.

The susceptor moving portion 830 may move the susceptor 820 by rotating due to driving from the outside, or may move the susceptor 820 by making the interior of the manufacturing apparatus 800 inclined such that the intake position X_{E1} is higher than the extraction position X_{E2}.

The gate valve 840 is provided at the intake position X_{E1} and the extraction position X_{E2}. By opening the gate valve 840, the susceptor 820 on which the semiconductor substrate 10 mounted can be taken into the manufacturing apparatus 800, or the susceptor 820 on which the semiconductor substrate 10 is mounted can be extracted from the interior of the manufacturing apparatus 800.

The heating element 815 is provided inside the manufacturing apparatus 800. The heating element 815 is covered with a thermal insulation material 813. A plurality of heating elements 815 may be provided inside the manufacturing apparatus 800.

The heating element 815 of the present example is provided to correspond to the low temperature side temperature raising position X_{R1}, the high temperature side temperature raising position X_{R2}, the deposition position X_{D}, the high temperature side temperature lowering position X_{L1}, and the low temperature side temperature lowering position X_{L2}.

The heating element 815 forms a temperature distribution inside the manufacturing apparatus 800. The heating element 815 of the present example forms, inside the manufacturing apparatus 800, a temperature distribution in which the temperature increases from the intake position X_{E1} and the extraction position X_{E2} to the deposition position X_{D}. The temperature at each position may be adjusted by changing the number of heaters 814 included in the heating element 815. In the present example, one heater 814 is provided at the low temperature side temperature raising position X_{R1} and the low temperature side temperature lowering position X_{L2}, two heaters 814 are provided at the high temperature side temperature raising position X_{R2} and the high temperature side temperature lowering position X_{L1}, and three heaters 814 are provided at the deposition position X_{D}, respectively. The temperature at each position may be adjusted by changing the heater output of the heater 814, or may be adjusted by changing the type of the heater 814.

The temperature of the semiconductor substrate 10 is raised from the extraction temperature to the deposition temperature by moving the semiconductor substrate 10 from the intake position X_{E1} to the deposition position X_{D}. The temperature of the semiconductor substrate 10 is lowered from the deposition temperature to the extraction temperature by moving the semiconductor substrate 10 from the deposition position X_{D} to the extraction position X_{E2}. In the present example, in accordance with the temperature distribution inside the manufacturing apparatus 800, the temperature of the semiconductor substrate 10 and the susceptor 820 is changed by moving the position of the semiconductor substrate 10 and the susceptor 820. Thereby, energy for raising the temperature of the heating element and energy for lowering the temperature of the heating element can be reduced.

In the manufacturing apparatus 800 of the present example, step S100 that raises the temperature of the semiconductor substrate 10 includes a step for moving the semiconductor substrate 10 from the intake position X_{E1} to the deposition position X_{D}. That is, the step for moving includes changing the position of the semiconductor substrate 10 relative to the deposition position X_{D}. In the manufacturing apparatus 800 of the present example, step S300 that lowers the temperature of the semiconductor substrate 10 includes a step for moving the semiconductor substrate 10 from the deposition position X_{D} to the extraction position X_{E2}. That is, the step for moving includes changing the position of the semiconductor substrate 10 relative to the deposition position X_{D}.

FIG. 11B shows an example of the manufacturing apparatus 800. FIG. 11B is an example of the manufacturing apparatus 800 in a top view. With reference to FIG. 11B, a gas flow inside the manufacturing apparatus 800 is described. Note that, in FIG. 11B, only configurations required for the description are illustrated, and descriptions of the other configurations are omitted.

The manufacturing apparatus 800 comprises a gas introduction tube 811 and a gas discharge pipe 812. A gas such as a carrier gas, an inert gas, and a raw material gas is introduced into the manufacturing apparatus 800 from the gas introduction tube 811. The introduced gas is discharged from the gas discharge pipe 812 to the outside.

In the manufacturing apparatus 800 of the present example, an inert gas is introduced at a position other than the deposition position X_{D}. In FIG. 11B, the flow of the inert gas is indicated with an arrow of a dashed line. In the manufacturing apparatus 800, only a carrier gas may be introduced at a position other than the deposition position X_{D}.

In the manufacturing apparatus 800 of the present example, at the deposition position X_{D}, a gaseous mixture compsed of a carrier gas and a raw material gas is locally introduced. In FIG. 11B, the flow of the gas mixture is indicated with an arrow of a solid line. Thereby, at the deposition position X_{D}, the semiconductor layer 20 can be deposited on the semiconductor substrate 10.

In the example of FIG. 11B, the example comprising the gas introduction tube 811 and the gas discharge pipe 812 that are common at the deposition position X_{D} and the position other than the deposition position X_{D} is illustrated, but it is not limited thereto. The gas introduction tube 811 and the gas discharge pipe 812 for introducing the gas mixture to the deposition position X_{D} may be different from the gas introduction tube 811 and the gas discharge pipe 812 for introducing the inert gas or the carrier gas to the position other than the deposition position X_{D}.

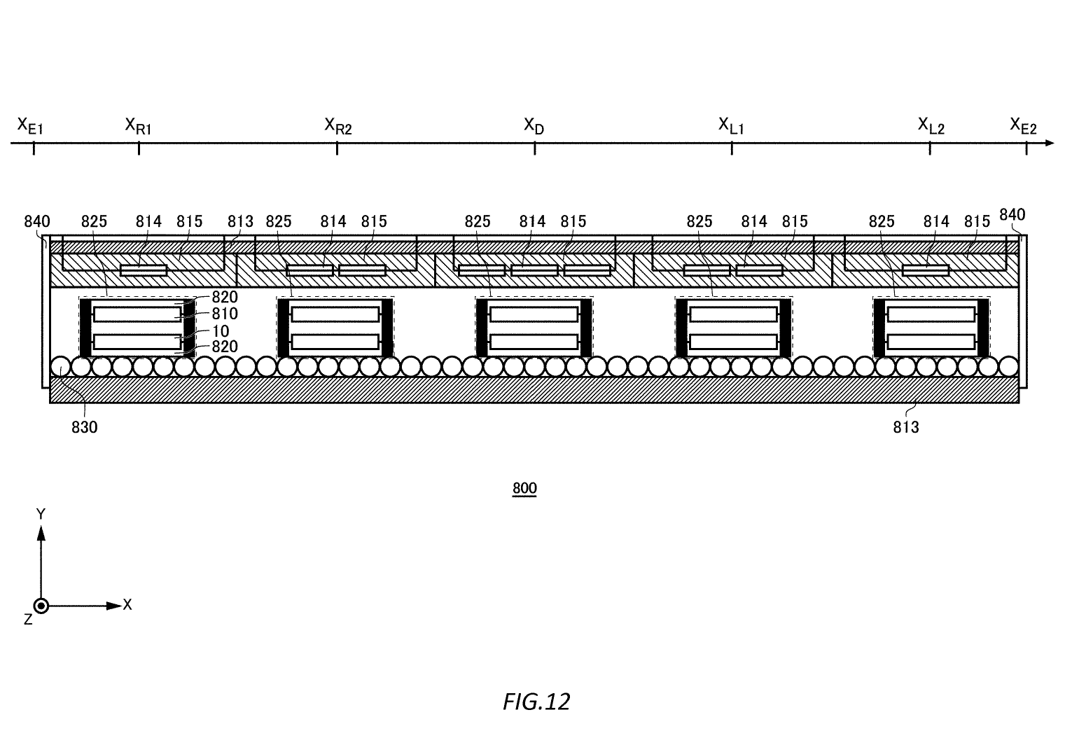

FIG. 12 shows a modified example of the manufacturing apparatus 800 of the semiconductor device 300. With reference to FIG. 12, a difference from FIG. 11A will be described.

In the example of FIG. 12, instead of the susceptor 820 on which the semiconductor substrate 10 is mounted, a deposition unit 825 is used. The deposition unit 825 includes a susceptor 820 on which a semiconductor substrate 10 is mounted, and a susceptor 820 on which a raw material substrate 810 is mounted.

The raw material substrate 810 is a substrate that is a raw material of the semiconductor layer 20. As an example, the raw material substrate 810 is a silicon carbide semiconductor substrate. The raw material substrate 810 is provided to face the semiconductor substrate 10.

The raw material substrate 810 is provided closer to the heating element 815 than the semiconductor substrate 10. Therefore, the raw material substrate 810 is heated to a temperature higher than that of the semiconductor substrate 10. As an example, the temperature of the raw material substrate 810 when the deposition unit 825 is moved to the deposition position X_{D} is 2200℃ or more, and 2400℃ or less.

Step S200 of the present example that deposits the semiconductor layer 20 includes depositing the semiconductor layer 20 using a close-spaced sublimation method. The close-spaced sublimation method is a type of Physical Vapor Deposition (PVD), and is an approach in which a raw material is transferred from a raw material substrate of high temperature to a substrate of low temperature by sublimation, to deposit a thin film of a desired substance. In the present example, if the deposition unit 825 is moved to the deposition position X_{D}, a raw material transfer by proximity sublimation is performed, by a temperature gradient, from the raw material substrate 810 to the semiconductor substrate 10, and the semiconductor layer 20 is deposited on the semiconductor substrate 10. Thereby, the gas mixture composed of the raw material gas and the carrier gas for depositing the semiconductor layer 20 is not required to be introduced from the outside, and therefore, the manufacturing apparatus 800 can be simplified. Note that, the interior or the manufacturing apparatus 800 may be maintained in an inert gas atmosphere introduced from the gas introduction tube 811.

While the present invention has been described by way of the embodiments, the technical scope of the present invention is not limited to the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described by using phrases such as "first" or "next" for the sake of convenience in the claims, specification, and drawings, it does not necessarily mean that the process must be performed in this order.

(Item 1)

A semiconductor device manufacturing method comprising:

raising a temperature of a semiconductor substrate from a predetermined intake temperature to a predetermined deposition temperature;

depositing, at a predetermined deposition position, a semiconductor layer on the semiconductor substrate at the deposition temperature; and

lowering a temperature of the semiconductor substrate from the deposition temperature to a predetermined extraction temperature;

wherein the raising and the lowering include at least one of:

in the raising, raising the temperature of the semiconductor substrate to a first substrate temperature that is higher than the intake temperature and lower than the deposition temperature by moving the semiconductor substrate from an intake position to a temperature raising position different from the deposition position, or

in the lowering, lowering the temperature of the semiconductor substrate to a second substrate temperature that is higher than the extraction temperature and lower than the deposition temperature by moving the semiconductor substrate from the deposition position to a temperature lowering position different from the deposition position.

(Item 2)

The semiconductor device manufacturing method according to item 1, wherein

the raising and the lowering include at least one of:

in the raising, moving the semiconductor substrate from a low temperature side temperature raising position to a high temperature side temperature raising position with a temperature higher than that of the low temperature side temperature raising position; or

in the lowering, moving the semiconductor substrate from a high temperature side temperature lowering position to a low temperature side temperature lowering position with a temperature lower than that of the high temperature side temperature lowering position.

(Item 3)

The semiconductor device manufacturing method according to item 1, wherein

the raising includes raising the temperature of the semiconductor substrate by bringing the semiconductor substrate close to a heating element that is heated to a predetermined temperature.

(Item 4)

The semiconductor device manufacturing method according to item 2, wherein

the low temperature side temperature raising position is further spaced apart from a heating element that raises a temperature of the semiconductor substrate to a predetermined deposition temperature than the high temperature side temperature raising position; or

the low temperature side temperature lowering position is further spaced apart from the heating element that raises the temperature of the semiconductor substrate to a predetermined deposition temperature than the high temperature side temperature lowering position; or

the high temperature side temperature raising position is closer to the heating element than the low temperature side temperature raising position, and further spaced apart from the heating element than the deposition position; or

the high temperature side temperature lowering position is closer to the heating element than the low temperature side temperature lowering position, and further spaced apart from the heating element than the deposition position.

(Item 5)

The semiconductor device manufacturing method according to item 1, wherein

a temperature raising rate in the raising is 30℃/min or more, and 1000℃/min or less.

(Item 6)

The semiconductor device manufacturing method according to item 1, wherein

a temperature lowering rate in the lowering is 50℃/min or more, and 1000℃/min or less.

(Item 7)

The semiconductor device manufacturing method according to any one of items 1 to 6, wherein

the raising includes raising a temperature of a plurality of semiconductor substrates, or

the lowering includes lowering the temperature of each of the plurality of semiconductor substrates, or

the raising includes raising the temperature of each of the plurality of semiconductor substrates, or the lowering includes lowering the temperature of each of the plurality of semiconductor substrates.

(Item 8)

The semiconductor device manufacturing method according to item 1, wherein

the raising includes raising a temperature of a plurality of semiconductor substrates,

the lowering includes lowering the temperature of a plurality of semiconductor substrates, and

in at least one of the raising or the lowering, the plurality of semiconductor substrates positioned at the temperature raising position are subjected to a heat exchange with the plurality of semiconductor substrates positioned at the temperature lowering position.

(Item 9)

The semiconductor device manufacturing method according to item 8, wherein

the plurality of semiconductor substrates positioned at the temperature raising position performs a heat exchange with the plurality of semiconductor substrates positioned at the temperature lowering position in a period during which a semiconductor layer is deposited on a plurality of semiconductor substrates positioned at the deposition position.

(Item 10)

The semiconductor device manufacturing method according to item 8, wherein

a temperature of each of the plurality of semiconductor substrates positioned at the temperature raising position is raised by supplying heat from the plurality of semiconductor substrates positioned at the temperature lowering position; and

a temperature of each of the plurality of semiconductor substrates positioned at the temperature lowering position is lowered by supplying heat to the plurality of semiconductor substrates positioned at the temperature raising position.

(Item 11)

The semiconductor device manufacturing method according to item 8, wherein in the raising:

a temperature of a plurality of semiconductor substrates positioned at a high temperature side temperature raising position is raised by supplying heat from a plurality of semiconductor substrates positioned at a high temperature side temperature lowering position; and

a temperature of a plurality of semiconductor substrates positioned at a low temperature side temperature raising position with a temperature lower than that of the high temperature side temperature raising position is raised by supplying heat from a plurality of semiconductor substrates positioned at a low temperature side temperature lowering position with a temperature lower than that of the high temperature side temperature lowering position; wherein in the lowering:

a temperature of each of the plurality of semiconductor substrates positioned at the high temperature side temperature lowering position is lowered by supplying heat to the plurality of semiconductor substrates positioned at the high temperature side temperature raising position; and

a temperature of each of the plurality of semiconductor substrates positioned at the low temperature side temperature lowering position is lowered by supplying heat to the plurality of semiconductor substrates positioned at the low temperature side temperature raising position.

(Item 12)

The semiconductor device manufacturing method according to any one of items 8 to 11, wherein in the raising, a temperature of each of the plurality of semiconductor substrates is:

in the temperature raising position, raised to the first substrate temperature from the intake temperature by a heat exchange; and

in the deposition position, raised to the deposition temperature from the first substrate temperature by a heating element for heating the plurality of semiconductor substrates.

(Item 13)

The semiconductor device manufacturing method according to any one of items 1 to 6 or 8 to 11, wherein

at least one of a temperature raising amount of the semiconductor substrate in the raising at the deposition position or a temperature lowering amount of the semiconductor substrate in the lowering at the deposition position is 50% or less, or 25% or less, or 12.5% or less, or 6.25% or less of a temperature difference between the deposition temperature and a room temperature.

(Item 14)

The semiconductor device manufacturing method according to any one of items 1 to 6 or 8 to 11, wherein

in the raising and the lowering, the moving the semiconductor substrate includes changing a position of the semiconductor substrate relative to the deposition position.

(Item 15)

The semiconductor device manufacturing method according to any one of items 1 to 6, wherein

the depositing includes depositing the semiconductor layer by a close-spaced sublimation method.

(Item 16)

A semiconductor device manufacturing apparatus comprising:

a deposition chamber for depositing a semiconductor layer on a semiconductor substrate that is positioned at a predetermined deposition position;

a heating element for raising a temperature of the semiconductor substrate to a predetermined deposition temperature in the deposition chamber; and

a distance adjusting portion for changing a distance between the semiconductor substrate and the heating element; wherein

the distance adjusting portion changes the distance between the semiconductor substrate and the heating element in a state in which a temperature of the semiconductor substrate is higher than a predetermined intake temperature or a predetermined extraction temperature, and lower than the deposition temperature.

(Item 17)

The semiconductor device manufacturing apparatus according to item 16, wherein

the distance adjusting portion:

raises a temperature of the semiconductor substrate positioned at a predetermined intake position to a first substrate temperature higher than the intake temperature and lower than the deposition temperature, by moving the semiconductor substrate to a temperature raising position that is closer to the heating element than the intake position and that is further spaced apart from the heating element than the deposition position; or

lowers the temperature of the semiconductor substrate to a second substrate temperature that is higher than the extraction temperature and lower than the deposition temperature by moving the semiconductor substrate to a temperature lowering position that is further spaced apart from the heating element than the deposition position.

(Item 18)

The semiconductor device manufacturing apparatus according to item 16, wherein

the distance adjusting portion includes:

a rotary element that rotates the semiconductor substrate in a top view; and

a distance change element for changing a distance between the semiconductor substrate and the heating element.

(Item 19)

The semiconductor device manufacturing apparatus according to item 18, comprising a susceptor for mounting the semiconductor substrate, wherein

the susceptor is provided to have a circular shape in a top view,

a length of the distance change element is five times or more and ten times or less of a radius of the susceptor.

(Item 20)

The semiconductor device manufacturing apparatus according to item 19, wherein

a thickness of the susceptor is 70% or more and 100% or less of a thickness of the semiconductor substrate.

(Item 21)

The semiconductor device manufacturing apparatus according to item 19, wherein

a thickness of the susceptor is 350 µm or more and 500 µm or less.

(Item 22)

The semiconductor device manufacturing apparatus according to any one of items 16 to 21, wherein

the heating element is heated by an electromagnetic induction.

(Item 23)

A semiconductor device manufacturing apparatus comprising:

a deposition chamber in which a semiconductor layer is deposited on a plurality of semiconductor substrates at a predetermined deposition position;

a heating element for raising a temperature of each of the plurality of semiconductor substrates to a predetermined deposition temperature in the deposition chamber; and

a heat exchanging portion for performing a heat exchange between a plurality of semiconductor substrates having different temperatures.

(Item 24)

The semiconductor device manufacturing apparatus according to item 23, comprising:

a boat in which the plurality of semiconductor substrates are mounted; and

a load lock chamber for extracting a boat in which the plurality of semiconductor substrates whose temperature has been lowered in the heat exchanging portion are mounted.

(Item 25)

The semiconductor device manufacturing apparatus according to item 24, comprising an evacuation portion for housing the boat, wherein

the boat moves between the heat exchanging portion and the deposition chamber via the evacuation portion.

### EXPLANATION OF REFERENCES

10: semiconductor substrate

12: source region

14: base region

15: contact region

16: first conductivity-type region

17: second conductivity type region

18: buffer region

20: semiconductor layer

21: front surface

23: back surface

24: back surface side electrode

30: substrate layer

38: interlayer dielectric film

40: gate trench portion

50: semiconductor substrate

52: front surface side electrode

54: contact hole

100: manufacturing apparatus

105: outer wall

110: deposition chamber

111: gas introduction tube

112: gas discharge pipe

113: thermal insulation material

114: inductive heating coil

115: heating element

120: susceptor

130: distance adjusting portion

131: rotary element

132: distance change element

133: rod element

140: gate valve

200: manufacturing apparatus

205: outer wall

210: deposition chamber

211: gas introduction tube

212: gas discharge pipe

214: inductive heating coil

215: heating element

220: boat

221: boat rotary element

222: hanging portion

223: thermal insulation material

230: heat exchanging portion

231: heat exchanging portion rotary element

232: upper member

233: thermal insulation material

234: lower member

235: heat exchange chamber

236: through hole

237: body

238: heating device

239: cooling apparatus

240: gate valve

250: evacuation portion

260: load lock chamber

270: boat moving mean

300: semiconductor device

500: manufacturing apparatus

510: deposition chamber

511: gas introduction tube

512: gas discharge pipe

513: thermal insulation material

514: inductive heating coil

515: heating element

520: susceptor

600: manufacturing apparatus

610: deposition chamber

611: gas introduction tube

612: gas discharge pipe

614: inductive heating coil

615: heating element

620: boat

621: boat rotary element

660: housing chamber

700: manufacturing apparatus

710: deposition chamber

711: gas introduction tube

712: gas discharge pipe

713: thermal insulation material

714: heater

715: heating element

720: susceptor

730: rotary lifting element

740: gate valve

780: temperature raising portion

781: low temperature side temperature raising chamber

782: high temperature side temperature raising chamber

790: temperature lowering portion

791: high temperature side temperature lowering chamber

792: low temperature side temperature lowering chamber

800: manufacturing apparatus

810: raw material substrate

811: gas introduction tube

812: gas discharge pipe

813: thermal insulation material

814: heater

815: heating element

820: susceptor

825: deposition unit

830: susceptor moving portion

840: gate valve.

What is claimed is:

1. A semiconductor device manufacturing method comprising:
raising a temperature of a semiconductor substrate from a predetermined intake temperature to a predetermined deposition temperature;
depositing, at a predetermined deposition position, a semiconductor layer on the semiconductor substrate at the deposition temperature; and
lowering a temperature of the semiconductor substrate from the deposition temperature to a predetermined extraction temperature;
wherein the raising and the lowering include at least one of:
in the raising, raising the temperature of the semiconductor substrate to a first substrate temperature that is higher than the intake temperature and lower than the deposition temperature by moving the semiconductor substrate from an intake position to a temperature raising position different from the deposition position, or
in the lowering, lowering the temperature of the semiconductor substrate to a second substrate temperature that is higher than the extraction temperature and lower than the deposition temperature by moving the semiconductor substrate from the deposition position to a temperature lowering position different from the deposition position.

2. The semiconductor device manufacturing method according to claim 1, wherein
the raising and the lowering include at least one of:
in the raising, moving the semiconductor substrate from a low temperature side temperature raising position to a high temperature side temperature raising position with a temperature higher than that of the low temperature side temperature raising position; or
in the lowering, moving the semiconductor substrate from a high temperature side temperature lowering position to a low temperature side temperature lowering position with a temperature lower than that of the high temperature side temperature lowering position.

3. The semiconductor device manufacturing method according to claim 1, wherein the raising includes raising the temperature of the semiconductor substrate by bringing the semiconductor substrate close to a heating element that is heated to a predetermined temperature.

4. The semiconductor device manufacturing method according to claim 1, wherein
the raising includes raising a temperature of a plurality of semiconductor substrates, or
the lowering includes lowering the temperature of each of the plurality of semiconductor substrates, or
the raising includes raising the temperature of each of the plurality of semiconductor substrates, or the lowering includes lowering the temperature of each of the plurality of semiconductor substrates.

5. The semiconductor device manufacturing method according to claim 1, wherein
the raising includes raising a temperature of a plurality of semiconductor substrates,
the lowering includes lowering the temperature of each of the plurality of semiconductor substrates, and
in at least one of the raising or the lowering, a plurality of semiconductor substrates positioned at the temperature raising position are subjected to a heat exchange with a plurality of semiconductor substrates positioned at the temperature lowering position.

6. The semiconductor device manufacturing method according to claim 5, wherein
the plurality of semiconductor substrates positioned at the temperature raising position performs a heat exchange with the plurality of semiconductor substrates positioned at the temperature lowering position in a period during which a semiconductor layer is deposited on a plurality of semiconductor substrates positioned at the deposition position.

7. The semiconductor device manufacturing method according to claim 5, wherein
a temperature of each of the plurality of semiconductor substrates positioned at the temperature raising position is raised by supplying heat from the plurality of semiconductor substrates positioned at the temperature lowering position; and
a temperature of each of the plurality of semiconductor substrates positioned at the temperature lowering position is lowered by supplying heat to the plurality of semiconductor substrates positioned at the temperature raising position.

8. The semiconductor device manufacturing method according to claim 5, wherein in the raising, a temperature of each of the plurality of semiconductor substrates is:
in the temperature raising position, raised to the first substrate temperature from the intake temperature by a heat exchange; and
in the deposition position, raised to the deposition temperature from the first substrate temperature by a heating element for heating the plurality of semiconductor substrates.

9. The semiconductor device manufacturing method according to claim 1, wherein
in the raising and the lowering, the moving the semiconductor substrate includes changing a position of the semiconductor substrate relative to the deposition position.

10. The semiconductor device manufacturing method according to claim 1, wherein
the depositing includes depositing the semiconductor layer by a close-spaced sublimation method.

11. A semiconductor device manufacturing apparatus comprising:
a deposition chamber for depositing a semiconductor layer on a semiconductor substrate that is positioned at a predetermined deposition position;
a heating element for raising a temperature of the semiconductor substrate to a predetermined deposition temperature in the deposition chamber; and
a distance adjusting portion for changing a distance between the semiconductor substrate and the heating element; wherein
the distance adjusting portion changes the distance between the semiconductor substrate and the heating element in a state in which a temperature of the semiconductor substrate is higher than a predetermined intake temperature or a predetermined extraction temperature, and lower than the deposition temperature.

12. The semiconductor device manufacturing apparatus according to claim 11, wherein
the distance adjusting portion:
raises a temperature of the semiconductor substrate positioned at a predetermined intake position to a first substrate temperature higher than the intake temperature and lower than the deposition temperature, by moving the semiconductor substrate to a temperature raising position that is closer to the heating element than the intake position and that is further spaced apart from the heating element than the deposition position; and
lowers the temperature of the semiconductor substrate to a second substrate temperature that is higher than the extraction temperature and lower than the deposition temperature by moving the semiconductor substrate to a temperature lowering position that is further spaced apart from the heating element than the deposition position.

13. The semiconductor device manufacturing apparatus according to claim 11, wherein
the distance adjusting portion includes:
a rotary element that rotates the semiconductor substrate in a top view; and
a distance change element for changing a distance between the semiconductor substrate and the heating element.

14. The semiconductor device manufacturing apparatus according to claim 13, comprising a susceptor for mounting the semiconductor substrate, wherein
the susceptor is provided to have a circular shape in a top view,
a length of the distance change element is five times or more and ten times or less of a radius of the susceptor.

15. The semiconductor device manufacturing apparatus according to claim 14, wherein
a thickness of the susceptor is 70% or more and 100% or less of a thickness of the semiconductor substrate.

16. The semiconductor device manufacturing apparatus according to claim 14, wherein
a thickness of the susceptor is 350 µm or more and 500 µm or less.

17. The semiconductor device manufacturing apparatus according to claim 11, wherein
the heating element is heated by an electromagnetic induction.

18. A semiconductor device manufacturing apparatus comprising:
a deposition chamber in which a semiconductor layer is deposited on a plurality of semiconductor substrates at a predetermined deposition position;
a heating element for raising a temperature of each of the plurality of semiconductor substrates to a predetermined deposition temperature in the deposition chamber; and
a heat exchanging portion for performing a heat exchange between a plurality of semiconductor substrates having different temperatures.

19. The semiconductor device manufacturing apparatus according to claim 18, comprising:
a boat in which the plurality of semiconductor substrates are mounted; and
a load lock chamber for extracting a boat in which the plurality of semiconductor substrates whose temperature has been lowered in the heat exchanging portion are mounted.

20. The semiconductor device manufacturing apparatus according to claim 19, comprising an evacuation portion for housing the boat, wherein
the boat moves between the heat exchanging portion and the deposition chamber via the evacuation portion.
